(19) United States
(12) Patent Application Publication
(10) Pub. No.: US 2025/0151398 A1
(43) Pub. Date: May 8, 2025

(54) ARRAY SUBSTRATE AND DISPLAY PANEL

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Zhengkun LI, Beijing (CN); Tinghua SHANG, Beijing (CN); Lili DU, Beijing (CN); Jiaxing CHEN, Beijing (CN); Zhongliu YANG, Beijing (CN); Yi AN, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/843,316

(22) PCT Filed: Oct. 19, 2023
(86) PCT No.: PCT/CN2023/125488

§ 371 Date: Sep. 3, 2024

(51) Int. Cl. H10D 86/40; H10D 86/60

(52) U.S. Cl. CPC H10D 86/443; H10D 86/60

(57) ABSTRACT

An array substrate has a hole-opening region, a display region surrounding the hole-opening region, and a hole-peripheral region located between the hole-opening region and the display region. The array substrate includes a substrate and a driving circuit layer located on the substrate. The driving circuit layer includes a constant-voltage conductive ring and a plurality of signal lines. At least some of the plurality of signal lines are target signal lines. The target signal lines each include a lead portion and a winding portion connected thereto. The lead portion extends from the hole-peripheral region to the display region, and the winding portion is located in the hole-peripheral region and is disposed along an edge of the hole-opening region. The constant-voltage conductive ring is located in the hole-peripheral region and is disposed around the hole-opening region. The winding portion is located between the constant-voltage conductive ring and the hole-opening region.

### CROSS-REFERENCE TO RELATED APPLICATION

This application is a national phase entry under 35 USC 371 of International Patent Application No. PCT/CN2023/125488 filed on Oct. 19, 2023, which is incorporated herein by reference in its entirety.

### TECHNICAL FIELD

The present disclosure relates to the field of display technologies, and in particular, to an array substrate and a display panel.

### BACKGROUND

Display apparatuses can be used to display images. With the rapid development of display technologies, the display apparatuses have gradually come throughout people's lives.

### SUMMARY

In an aspect, an array substrate is provided. The array substrate has a hole-opening region, a display region surrounding the hole-opening region, and a hole-peripheral region located between the hole-opening region and the display region. The array substrate includes a substrate and a driving circuit layer located on the substrate. The driving circuit layer includes a constant-voltage conductive ring and a plurality of signal lines. The plurality of signal lines include a plurality of target signal lines, the target signal lines each include a lead portion and a winding portion connected thereto, the lead portion extends from the hole-peripheral region to the display region, and the winding portion is located in the hole-peripheral region and is disposed along an edge of the hole-opening region. The constant-voltage conductive ring is located in the hole-peripheral region and is disposed around the hole-opening region; and an orthographic projection of the winding portion on the substrate is located between an orthographic projection of the constant-voltage conductive ring on the substrate and the hole-opening region.

In some embodiments, the lead portion includes a first overlapping portion, an orthographic projection of the first overlapping portion on the substrate overlaps the orthographic projection of the constant-voltage conductive ring on the substrate, and areas of first overlapping portions of lead portions of the plurality of target signal lines are equal.

In some embodiments, the plurality of target signal lines include a plurality of first signal lines, and lead portions of the plurality of first signal lines extend along a first direction and are arranged along a second direction, the first direction intersecting the second direction; and the plurality of first signal lines are divided into signal lines of a first part and signal lines of a second part; and along the second direction, lead portions of the signal lines of the first part and lead portions of the signal lines of the second part are located at two sides of the hole-opening region, respectively.

In some embodiments, the plurality of target signal lines further include a plurality of second signal lines, and lead portions of the plurality of second signal lines extend along the second direction and are arranged in the first direction; and the plurality of second signal lines are divided into signal lines of a third part and signal lines of a fourth part; and along the first direction, lead portions of the signal lines of the third part and lead portions of the signal lines of the fourth part are located at two sides of the hole-opening region, respectively.

In some embodiments, the first signal lines include gate control signal lines, and the second signal lines include data signal lines.

In some embodiments, the driving circuit layer includes multiple metal conductive layers stacked on the substrate. Along a direction away from the substrate, the multiple metal conductive layers are a first gate metal layer, a second gate metal layer, a first wiring metal layer, and a second wiring metal layer. In the plurality of first signal lines: winding portions of a part of the first signal lines are located in the first gate metal layer, and winding portions of another part of the first signal lines are located in the second gate metal layer; and in the plurality of second signal lines: winding portions of a part of the second signal lines are located in the first wiring metal layer, and winding portions of another part of the second signal lines are located in the second wiring metal layer.

In some embodiments, in a plurality of winding portions of the plurality of signal lines, a winding portion whose orthographic projection on the substrate is furthest away from the hole-opening region is an outer winding portion. The driving circuit layer further includes a dummy winding portion, where the dummy winding portion is located between the outer winding portion and the display region, and the dummy winding portion is in a same layer as the outer winding portion.

In some embodiments, in multiple winding portions located in a same metal conductive layer, a winding portion farthest from the hole-opening region is an edge winding portion. The driving circuit layer further includes dummy winding portions. The dummy winding portions are in one-to-one correspondence with edge winding portions, and the dummy winding portions are each located between a corresponding edge winding portion and the display region, and the dummy winding portions are each located in a same layer as the corresponding edge winding portion.

In some embodiments, in a direction from the hole-opening region to the display region, a width of the dummy winding portion is equal to a width of the winding portion.

In some embodiments, in a direction from the hole-opening region to the display region, a distance between the dummy winding portion and the outer winding portion adjacent thereto is equal to a distance between any two adjacent winding portions.

In some embodiments, in a plurality of winding portions of the plurality of signal lines, a winding portion whose orthographic projection on the substrate is furthest away from the hole-opening region is an outer winding portion; and other than the outer winding portion, winding portions in the plurality of winding portions are each a first inner winding portion; and in a direction from the hole-opening region to the display region, a width of the outer winding portion is d1, and a width of the first inner winding portion is d2, d1 being greater than d2.

In some embodiments, in multiple winding portions located in a same metal conductive layer, a winding portion farthest from the hole-opening region is an edge winding portion; and other than the edge winding portion, winding portions in the multiple winding portions are each a second inner winding portion; and in a direction from the hole-opening region to the display region, a width of the edge winding portion is d1, and a width of the second inner winding portion is d2, d1 being greater than d2.

In some embodiments, 1.1d2≤d1≤1.15d2.

In some embodiments, d1=1.3d2.

In some embodiments, the driving circuit layer further includes a plurality of pixel driving circuits, a pixel driving circuit of the plurality of pixel driving circuits includes a driving transistor, and the plurality of pixel driving circuits are located in the display region. The driving circuit layer further includes a bottom shielding layer, located between the pixel driving circuits and the substrate, where the constant-voltage conductive ring is electrically connected to the bottom shielding layer. The bottom shielding layer includes a plurality of shielding patterns, and an orthographic projection of a shielding pattern of the plurality of shielding patterns on the substrate covers an orthographic projection of the driving transistor on the substrate, and two adjacent shielding patterns are connected to each other.

In some embodiments, the constant-voltage conductive ring is in a same layer as the bottom shielding layer.

In some embodiments, the bottom shielding layer further includes a conductive connection portion, and the conductive connection portion is connected between the constant-voltage conductive ring and the shielding pattern. The driving circuit layer further includes a plurality of connection through-holes, and an orthographic projection of the conductive connection portion on the substrate is non-overlapping with orthographic projections of the connection through-holes on the substrate.

In some embodiments, a minimum distance between an orthographic projection of the conductive connection portion on the substrate and an orthographic projection of a connection through-hole of the plurality of connection through-holes on the substrate is greater than or equal to 3 μm.

In some embodiments, the conductive connection portion is in a same layer as the constant-voltage conductive ring. The conductive connection portion includes a first conductive connection portion, and the first conductive connection portion intersects the constant-voltage conductive ring to form a first acute angle and a first space. The driving circuit layer further includes a first compensation portion, and the first compensation portion is in the same layer as the constant-voltage conductive ring; and the first compensation portion is located in the first space, the first compensation portion intersects the first conductive connection portion to form a first included angle, and the first compensation portion intersects the constant-voltage conductive ring to form a second included angle, where the first included angle and the second included angle are both greater than or equal to 90°.

In another aspect, a display panel is provided. The display panel includes a light-emitting device layer and the array substrate as described in any of the above embodiments. The light-emitting device layer is located on a side of the array substrate away from the substrate.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus in accordance with some embodiments;

FIG. 2 is a structural diagram of a display panel in accordance with some embodiments:

FIG. 3 is a sectional view of a display panel in accordance with some embodiments;

FIG. 4 is a structural diagram of an array substrate in accordance with some achievable methods;

FIG. 5 is a sectional view of an array substrate in accordance with some embodiments:

FIG. 6 is a partially enlarged view of the region M1 in FIG. 4;

FIG. 7 is a partially enlarged view of the region M2 in FIG. 4;

FIG. 8 is a partially enlarged view of the region M3 in FIG. 4;

FIG. 9 is a diagram illustrating a connection between a bottom shielding layer and a constant-voltage conductive ring in the M2 region of FIG. 4:

FIG. 10 is a structural diagram of an array substrate in accordance with some embodiments:

FIG. 11 is a partially enlarged view of the region N3 in FIG. 10;

FIG. 12 is a partially enlarged view of the region K in FIG. 11;

FIG. 13 is a sectional view taken along the line I-I′ in FIG. 10;

FIG. 14 is another partially enlarged view of the region N3 in FIG. 10;

FIG. 15 is a sectional view taken along the line H1-H1′ in FIG. 14;

FIG. 16 is yet another partially enlarged view of the region N3 in FIG. 10:

FIG. 17 is a sectional view taken along the line H2-H2′ in FIG. 16;

FIG. 18 is still another partially enlarged view of the region N3 in FIG. 10;

FIG. 19 is a sectional view taken along the line H3-H3′ in FIG. 18;

FIG. 20 is still yet another partially enlarged view of the region N3 in FIG. 10; and

FIG. 21 is a sectional view taken along the line H4-H4′ in FIG. 20.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a/the plurality of” means two or more unless otherwise specified.

In the description of some embodiments, the terms such as “coupled” and “connected” and derivatives thereof may be used. The term “connected” should to be understood in a broad sense. For example, the term “connected” may represent a fixed connection, or a detachable connection, or a one-piece connection; and the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

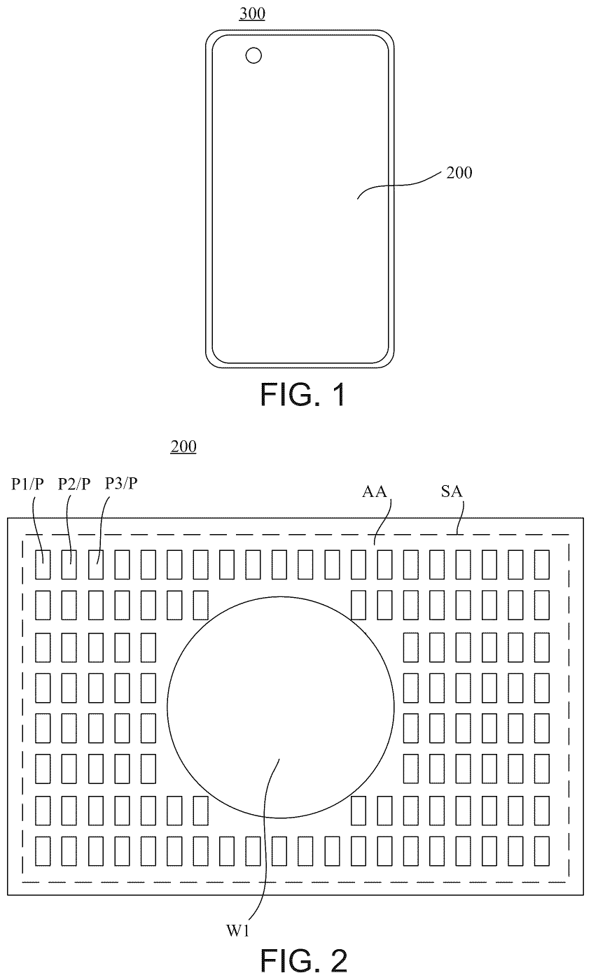

FIG. 1 is a structural diagram of a display apparatus in accordance with some embodiments.

As shown in FIG. 1, some embodiments of the present disclosure provide a display apparatus 300, and the display apparatus 300 includes a display panel 200.

For example, the display apparatus 300 further includes a frame and other electronic components.

By way of example, the display apparatus 300 may be an electroluminescent display apparatus or a photoluminescent display apparatus. In a case where the display apparatus is the electroluminescent display apparatus, the electroluminescent display apparatus may be an organic electroluminescent (organic light-emitting diode, OLED for short) display apparatus or a quantum dot electroluminescent (quantum dot light-emitting diode, OLED for short) display apparatus. In a case where the display apparatus is the photoluminescent display apparatus, the photoluminescent display apparatus may be a quantum dot photoluminescent display apparatus.

By way of example, the display apparatus 300 may be any apparatus capable of displaying images whether in motion (e.g., videos) or stationary (e.g., static images), and whether textual or graphical. More specifically, it is expected that the embodiments may be implemented in or associated with a plurality of electronic devices. The plurality of electronic devices may include (but are not limited to), for example, mobile telephones, wireless devices, personal data assistants (PDA), hand-held or portable computers, GPS receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc.

Some embodiments of the present disclosure provide a display panel. The display panel may serve as the display panel in the display apparatus provided in any of the above embodiments. Of course, the display panel may also be used in other display apparatuses, and the present disclosure is not limited thereto.

FIG. 2 is a structural diagram of a display panel in accordance with some embodiments, illustrating structures in a display region of the display panel. It will be noted that FIG. 2 illustrates only the structures in the display region of the display panel and omits structures in a peripheral region, for example, omitting a scanning driving circuit.

In some embodiments, as shown in FIG. 2, the display panel 200 includes a light-transmitting region W1, the display region (active area, AA for short, which may also be referred to as an effective display region) AA, and the peripheral region SA. The display region AA surrounds the light-transmitting region W1, and the peripheral region SA may be located on at least one side of the display region AA (for example, on one side; as another example, on all sides, i.e., including the upper and lower sides and the left and right sides).

The display panel 200 includes a plurality of sub-pixels P disposed in the display region AA. The light-transmitting region W1 is provided with no sub-pixel P therein.

Here, the plurality of sub-pixels P may be arranged in an array. Through light emitted by the plurality of sub-pixels P, the display panel 200 can display an image in the display region AA.

The plurality of sub-pixels P may include a plurality of sub-pixels for emitting light of different colors. By way of example, the plurality of sub-pixels P include first sub-pixels P1, second sub-pixels P2, and third sub-pixels P3. The first sub-pixels P1, the second sub-pixels P2, and the third sub-pixels P3 can emit light of three primary colors, respectively. For example, the first sub-pixels P1 may emit red light, the second sub-pixels P2 may emit green light, and the third sub-pixels P3 may emit blue light.

Based on the above, by adjusting brightness (grayscale) of sub-pixels P of different colors, a variety of colors can be displayed by combination and superposition of the colors, thereby realizing a full-color display of the display panel 200.

In some examples, as shown in FIG. 2, the light-transmitting region W1 may be in a shape of a circle. However, the embodiments of the present disclosure do not limit the shape of the light-transmitting region W1. For example, the light-transmitting region W1 may also be in the shape of a rectangle, an ellipse, or the like.

By way of example, the light-transmitting region W1 may be an imaging region, a fingerprint identification region, or the like. The following is taken as only an example with the light-transmitting region W1 as the camera region, and is also applicable for the fingerprint identification.

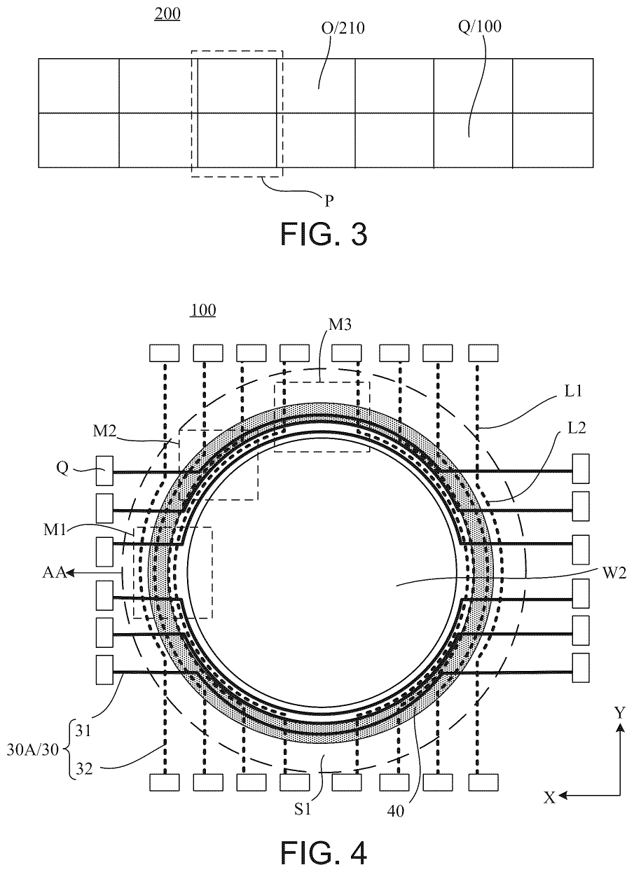

FIG. 3 is a sectional view of a display panel in accordance with some embodiments.

As shown in combination with FIG. 2 and FIG. 3, a sub-pixel P may include a light-emitting device O and a pixel driving circuit Q coupled to this light-emitting device O.

Here, the light-emitting device O may be one of, but is not limited to, an organic light-emitting diode (OLED), a quantum dot light-emitting diode (OLED), a light-emitting diode (LED), and a liquid crystal light-emitting device. The embodiments of the present disclosure do not limit the type of light-emitting device, i.e., the light-emitting device O may be any other light-emitting device (e.g., a light-emitting device that can emit light by discharging), as long as the light-emitting device can emit light to enable the display panel 200 to display images.

The pixel driving circuit Q may be configured to, in response to a scanning signal and a data signal that are received thereby, provide an electrical signal (e.g., a driving voltage or driving current) to the light-emitting device O coupled to the pixel driving circuit Q to drive the light-emitting device O to emit light, so as to enable the display panel 200 to display images.

As shown in FIG. 3, the display panel 200 includes an array substrate 100 and a light-emitting device layer 210 that are stacked in sequence, in which the light-emitting device layer 210 is located on a side of the array substrate 100 proximate to a light-exit surface of the display panel 200.

Here, the array substrate 100 includes a plurality of pixel driving circuits Q, the light-emitting device layer 210 includes a plurality of light-emitting devices O, and the plurality of pixel driving circuits Q are electrically connected to the plurality of light-emitting devices O to drive the light-emitting devices O to emit light.

In some examples, the plurality of pixel driving circuits Q and the plurality of light-emitting devices O described above may be electrically connected in one-to-one correspondence. In some other examples, one pixel driving circuit Q may be coupled to multiple light-emitting devices O, or multiple pixel driving circuits Q may be coupled to one light-emitting device O. In the following, the present disclosure schematically describes the structure of the display panel 200 by considering an example in which one pixel driving circuit Q is coupled to one light-emitting device O.

In some examples, the light-emitting device layer 210 includes an anode layer, a light-emitting functional layer, and a cathode layer that are stacked in sequence, in which the light-emitting functional layer includes light-emitting layers.

In some other examples, in addition to the light-emitting layers, the light-emitting functional layer 32 further includes one or more types of layers of electron transport layers (ETL), electron injection layers (EIL), hole transport layers (HTL) and hole injection layer (HIL).

In some examples, the display panel 200 further includes an encapsulation layer, and the encapsulation layer is located on a side of the light-emitting device layer 210 away from the array substrate 100. Here, the encapsulation layer may be an encapsulation film or an encapsulation substrate.

The encapsulation layer is capable of covering the plurality of light-emitting devices O in the light-emitting device layer 210, encapsulating the light-emitting devices O to prevent water vapor and oxygen in the external environment from entering into the display panel 200, damaging organic materials in the light-emitting devices O and shortening the lifespan of the display panel 200.

Some embodiments of the present disclosure provide an array substrate. The array substrate may serve as the array substrate in the display panel provided in any of the above embodiments. Of course, the array substrate may also be used in other display panels, and the present disclosure is not limited thereto.

FIG. 4 is a structural diagram of an array substrate in accordance with some achievable methods, and FIG. 4 illustrates signal lines around a hole-opening region W2 within a display region of the array substrate. It will be noted that FIG. 4 illustrates only the signal lines around the hole-opening region W2 within the display region of the array substrate, while omitting other structures around the hole-opening region W2. For example, structures such as pixel driving circuits around the hole-opening region W2 are omitted.

In some embodiments, as shown in FIG. 4, the array substrate 100 includes a hole-opening region W2, a display region (active area, AA for short, which may also be referred to as an effective display region) AA, and a hole-peripheral region S1. The display region AA surrounds the hole-opening region W2; and the hole-peripheral region S1 surrounds the hole-opening region W2, and is located between the hole-opening region W2 and the display region AA.

Here, the display region AA of the array substrate 100 may correspond to the display region AA of the above-described display panel 200 (as shown in FIG. 2); and the hole-opening region W2 of the array substrate 100 may correspond to the light-transmitting region W1 of the above-described display panel 200.

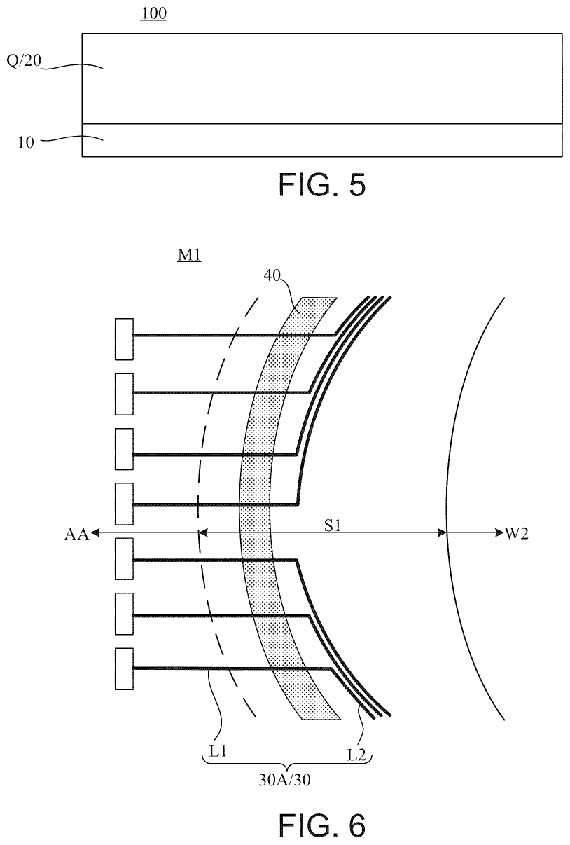

FIG. 5 is a sectional view of an array substrate in accordance with some embodiments.

In some embodiments, shown in combination with FIG. 4 and FIG. 5, the array substrate 100 includes a substrate 10 and a driving circuit layer 20 located on the substrate 10, in which the driving circuit layer 20 is located on a side of the substrate 10. By way of example, the driving circuit layer 20 is located on the side of the substrate 10 proximate to the light-emitting device layer 210 (as shown in FIG. 3). The driving circuit layer 20 includes a plurality of pixel driving circuits Q.

In some examples, the substrate 10 may be a flexible substrate. By way of example, a material of the substrate 10 may be an organic material. For example, the material of the substrate 10 may be any one of polyimide (P1), polycarbonate (PC) or polyvinyl chloride (PVC).

In some other examples, the substrate 10 may be a rigid substrate. By way of example, the rigid substrate may be a glass substrate or a polymethyl methacrylate (PMMA) substrate.

In some examples, the driving circuit layer 20 includes a plurality of pixel driving circuits Q disposed in the display region AA, in which the hole-opening region W2 is provided with no pixel driving circuit Q therein. A pixel driving circuit Q may be configured to, in response to a scanning signal and a data signal that are received thereby, provide an electrical signal (e.g., a driving voltage or driving current) to a light-emitting device O coupled to the pixel driving circuit Q to drive the light-emitting device O to emit light, so as to enable the display panel 200 to display images.

Here, the plurality of pixel driving circuits Q are arranged in multiple rows and multiple columns. For convenience of description, the plurality of pixel driving circuits Q described above in the present disclosure are described as an example arranged in a matrix form.

In some examples, a pixel driving circuit Q may include multiple transistors and at least one (e.g., one or multiple) capacitor. A driving transistor is included in the plurality of transistors. A variety of structures may be applied to the pixel driving circuit Q in the present disclosure, which may be selected and set according to actual needs. For example, a structure of the pixel driving circuit Q may include “2T1C”, “6T1C”, “T1 C”, “6T2C”, “7T2C”, “8T1C”, or the like. Here, “T” denotes a transistor (e.g., a thin film transistor), and a numerical digit located in front of “T” denotes the number of thin-film transistors; and C” denotes a capacitor (e.g., a storage capacitor) C, and a numerical digit located in front of “C” denotes the number of storage capacitors.

In some embodiments, as shown in combination with FIG. 4 and FIG. 5, a pixel driving circuit Q is required to be electrically connected to multiple signal lines 30, with different signals provided through the multiple signal lines 30 to provide the pixel driving circuit Q with desired signals.

In some examples, the plurality of signal lines 30 include a plurality of first signal lines 31, and lead portions L1 of the plurality of first signal lines 31 extend along a first direction X and are arranged along second direction Y Here, a first signal line 31 may be a gate control signal line, and a plurality of gate control signal lines are used to provide scanning signals. Here, the first direction X intersects the second direction Y.

The plurality of signal lines 30 further include a plurality of second signal lines 32, and lead portions L1 of the plurality of second signal lines 32 extend along the second direction Y and are arranged along the first direction X. A second signal line 32 may be a data signal line, and a plurality of data signal lines are used to provide data signals.

Based on the above, the pixel driving circuit Q may be configured to, in response to a scanning signal and a data signal that are received thereby, provide an electrical signal (e.g., a driving voltage or driving current) to the light-emitting device O coupled to the pixel driving circuit Q to drive the light-emitting device O to emit light, so as to enable the display panel 200 to display images.

In some examples, the first direction X may be set approximately perpendicular to the second direction Y. In this case, an included angle between the first direction X and the second direction Y is approximately equal to 90° for example, the included angle between the first direction X and the second direction Y may be 85°, 90°, or 95°.

The plurality of pixel driving circuits Q are all located in the display region AA, and the hole-opening region W2 is provided with no pixel driving circuit Q therein, so at least some of the plurality of signal lines 30 will pass through the hole-opening region W2 to provide electrical signals (such as scanning signals, data signals, and the like) to pixel driving circuits Q that are in their path and located on both sides of the hole-opening region W2.

In the plurality of signal lines 30, signal lines 30, which will pass through the hole-opening region W2, are target signal lines 30A. Here, “passing through” can mean that an orthographic projection of the signal line 30 on the substrate 10 overlaps the hole-opening region W2.

Since the target signal lines 30A are generally made of a metal material, when the target signal lines 30A pass through the hole-opening region W2, the target signal lines 30A will shield light, which will lead to a reduction in the light transmittance of the hole-opening region W2 of the array substrate 100, affecting the imaging effect of the display panel formed subsequently.

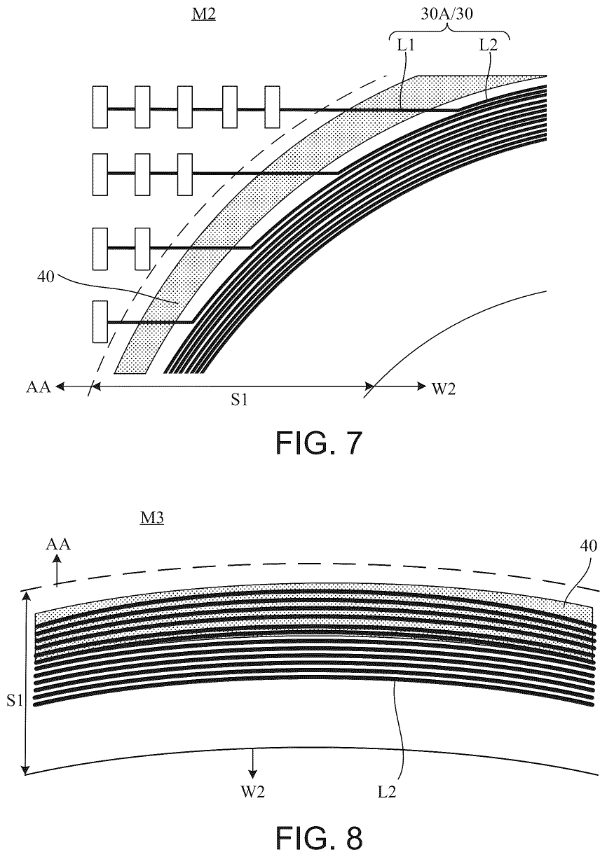

FIG. 6 is a partially enlarged view of the region M1 in FIG. 4, FIG. 7 is a partially enlarged view of the region M2 in FIG. 4, and FIG. 8 is a partially enlarged view of the region M3 in FIG. 4. Among them, FIG. 6 illustrates a structure of the hole-peripheral region S1 proximate to positions where winding portions L2 of a plurality of target signal lines 30A are connected to ends of lead portions L1 of the plurality of target signal lines 30A, FIG. 7 illustrates a structure of the hole-peripheral region S1 proximate to positions of ends of the winding portions L2 of the plurality of target signal lines 30A, and FIG. 8 illustrates a structure of the hole-peripheral region S1 proximate to intermediate positions of the winding portions L2 of the plurality of target signal lines 30A.

Based on the above, as shown in combination with FIG. 4 to FIG. 8, the plurality of target signal lines 30A need to avoid the hole-opening region W2. Thus, a target signal line 30A may include a lead portion L1 and a winding portion L2 connected thereto, the lead portion L1 extends from the hole-peripheral region S1 to the display region, and the winding portion L2 is located in the hole-peripheral region S1 and is disposed along an edge of the hole-opening region W2.

Here, FIG. 4 and FIG. 6 illustrate that the target signal line 30A is separated into two lead portions L1 by the hole-opening region W2, and the above two lead portions L1 are connected by the winding portion L2 located in the hole-peripheral region S1 to form the target signal line 30A avoiding the hole-opening region W2.

In some examples, all of the plurality of signal lines 30 may be set as target signal lines 30A.

In some other examples, a part of the plurality of signal lines 30 may be the target signal lines 30A. In this case, the other part of the plurality of signal lines 30 may be conventional signal lines. Here, the conventional signal lines are signal lines 30 in the plurality of signal lines 30 that do not pass through the hole-opening region W2. That is, orthographic projections of the conventional signal lines on the substrate 10 are non-overlapping with the hole-opening region W2.

The number of the target signal lines 30A in the plurality of signal lines 30 may be set according to a length of the hole-opening region W2 in a direction along which the plurality of signal lines 30 are arranged, and the present disclosure is not limited thereto.

The inventors have found through research that as shown in combination with FIG. 4 and FIG. 5, in order to prevent the light transmittance of the hole-opening region W2 from being affected, the plurality of pixel driving circuits Q in the driving circuit layer 20 are all disposed in the display region AA, and the light-transmitting region W1 is provided with no pixel driving circuit Q therein. As a result, part of structures in the driving circuit layer 20 is cut off in the light-transmitting region W1. For example, a bottom shielding layer in the driving circuit layer 20 is disconnected at a position of the light-transmitting region W1.

For the above reason, it will cause static electricity to be accumulated on the driving circuit layer 20 on a side of the display region AA proximate to the hole-opening region W2. When the accumulated static electricity has too much energy, it is easy to interfere with those pixel driving circuits Q in the driving circuit layer 20 which are at a position of the display region AA proximate to the hole-opening region W2, and even damage the pixel driving circuits Q at this position, reducing the quality of the array substrate 100.

The following examples describe structures in the driving circuit layer 20 that will be cut off in the light-transmitting region W1.

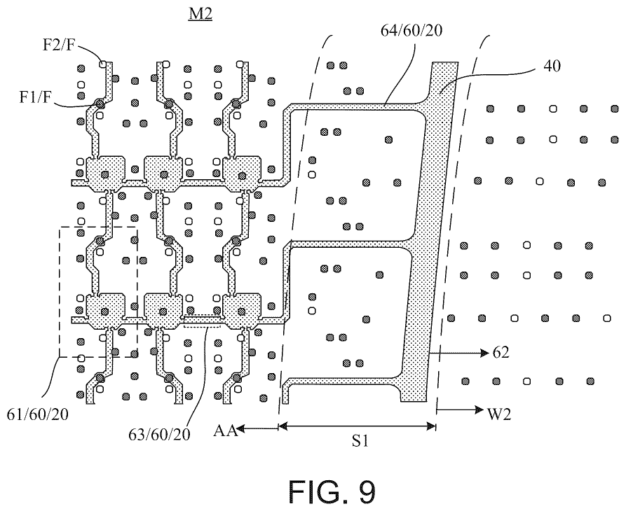

FIG. 9 is a diagram illustrating a connection between a bottom shielding layer and a constant-voltage conductive ring in the M2 region of FIG. 4.

In some embodiments, as shown in combination with FIG. 4 and FIG. 9, the driving circuit layer 20 further includes a bottom shielding layer (bottom shield metal, BSM for short) 60, and the bottom shielding layer 60 is located between the pixel driving circuits Q and the substrate 10. The bottom shielding layer 60 includes a plurality of shielding patterns 61, and an orthographic projection of a shielding pattern 61 on the substrate 10 covers an orthographic projection of a driving transistor in a pixel driving circuit Q on the substrate 10.

Based on the above, the bottom shielding layer 60 may be utilized to shield the static electricity to eliminate the influence on a driving transistor in each pixel driving circuit Q. In addition, the bottom shielding layer 60 may also serve as a light-shielding layer to reduce the influence caused to the pixel driving circuits Q by external light incident from a side where the substrate 10 is located.

In some examples, as shown in combination with FIG. 4 and FIG. 9, orthographic projections of the driving transistors in the pixel driving circuits Q on the substrate 10 is located within a boundary of the orthographic projection of the bottom shielding layer 60 on the substrate 10, so that the bottom shielding layer 60 can completely cover the driving transistors to eliminate the influence of the static electricity on the driving transistors.

In addition, two shielding patterns 61 corresponding to two adjacent pixel driving circuits Q may be electrically connected through a conductive portion 63, thereby reducing the impedance of the bottom shielding layer 60.

In some examples, the bottom shielding layer 60 is configured to receive a first power supply signal. In this way, the accumulated static electricity generated by the bottom shielding layer 60 may be reduced.

In some examples, in addition to being electrically connected to the pluralities of first signal lines 31 and second signal lines 32, the pixel driving circuits Q also need to be electrically connected to a first power supply signal line. The first power supply signal line is configured to provide the first power supply signal to the pixel driving circuits Q.

When a pixel driving circuit Q is in a light-emitting stage, the first power supply signal (e.g., a constant-voltage power supply signal) provided by the first power supply signal line can flow to an anode of a light-emitting device O (as shown in FIG. 3) through a driving transistor thereof, and a cathode of the light-emitting device O may be electrically connected to a second power supply signal line, which can drive the light-emitting device O to emit light. Here, the first power supply signal line may be a high power supply signal line, and the second power supply signal line may be a low power supply signal line, where a voltage value of a second power supply signal provided by the second power supply signal line is less than a voltage value of the first power supply signal provided by the first power supply signal line.

In light of this, the bottom shielding layer 60 may be arranged to be electrically connected to the first power supply signal line. In this way, there is no need to additionally provide a separate signal line in the driving circuit layer 20 for providing the first power supply signal to the bottom shielding layer 60. This may facilitate saving the space of the driving circuit layer 20, which is conducive to the subsequent flexible arrangement of other lines in the driving circuit layer 20.

The plurality of pixel driving circuits Q in the driving circuit layer 20 are all disposed in the display region AA, and the hole-opening region W2 is provided with no pixel driving circuit Q therein, so the bottom shielding layer 60 also needs to be provided with an avoidance opening region 62, as shown in FIG. 9, where the hole-opening region W2 is located within a boundary of the avoidance opening region 62.

In this way, the plurality of shielding patterns 61 in the bottom shielding layer 60 need to be separated at the avoidance opening region 62. That is, multiple shielding patterns 61 in the bottom shielding layer 60 need to be arranged around the hole-opening region W2.

Since some shielding patterns 61 arranged around the hole-opening region W2 are not connected to other structures on a side thereof proximate to the hole-opening region W2, these shielding patterns 61 are in an idle state at the side thereof proximate to the hole-opening region W2. This will result in static electricity charges being concentrated on concave-convex structures formed on the side of these shielding patterns 61 proximate to the hole-opening region W2 (similar to a shape of tip discharge). When the accumulated static electricity has too much energy, the static electricity will be firstly directed out through the tip according to the law of the tip discharge, which will lead to the tip discharge phenomenon easily occurring on the side of these shielding patterns 61 proximate to the hole-opening region W2, easily damaging pixel driving circuits Q proximate to the hole-opening W2, and decreasing the quality of the array substrate 100.

In some embodiments, as shown in FIG. 9, the bottom shielding layer 60 further includes conductive connection portions 64, and the conductive connection portions 64 are used to connect the constant-voltage conductive ring 40 and multiple shielding patterns 61 adjacent to the hole-opening region W2.

In the driving circuit layer 20, transistors in a pixel driving circuit Q need to be electrically connected to other transistors, or some transistors also need to be electrically connected to signal line(s) 30. The above electrical connection can generally be achieved through via-holes. In light of this, the driving circuit layer 20 may include a plurality of connection through-holes F.

Orthographic projections of the conductive connection portions 64 on the substrate 10 are arranged to be non-overlapping with orthographic projections of the connection through-holes F on the substrate 10, so as to prevent external water vapor from entering the interior of the driving circuit layer 20 via the connection through-holes F, where the external water vapor entering the interior of the driving circuit layer 20 will reduce the lifespan of the bottom shielding layer 60, the conductive connection portions 64, and other structures, thereby causing a problem of growing dark spots (GDS).

In some examples, the connection through-holes F may include first connection through-holes F1, where the first connection through-holes F1 are through-holes located in interlayer dielectric layer(s) each between a gate metal layer and a wiring metal layer.

In some examples, the connection through-holes F may further include second connection through-holes F2. In a case where the pixel driving circuits Q each include an indium gallium zinc oxide (IGZO) transistor The second connection through-holes F2 may each be a through-hole connecting the IGZO transistor and a signal line.

In some embodiments, as shown in FIG. 9, a minimum distance between an orthographic projection of a conductive connection portion 64 on the substrate 10 and an orthographic projection of a connection through-hole F on the substrate 10 is greater than or equal to 3 μm.

In a case where the minimum distance between the orthographic projection of the conductive connection portion 64 on the substrate 10 and the orthographic projection of the connection through-hole F on the substrate 10 is equal to or approaching 3 μm, it can not only ensure the distance between the conductive connection portion 64 and the connection through-hole F to alleviate the problem of GDS defect, but also prevent the distance between the conductive connection portion 64 and the connection through-hole F from being too large, where the too large distance between the conductive connection portion 64 and the connection through-hole F will result in too much space of the array substrate 100 being occupied, thereby causing a problem of reducing the flexibility of a layout of the array substrate 100.

In some examples, the minimum distance between the orthographic projection of the conductive connection portion 64 on the substrate 10 and the orthographic projection of the connection through-hole F on the substrate 10 is greater than or equal to 5 μm.

In a case where the minimum distance between the orthographic projection of the conductive connection portion 64 on the substrate 10 and the orthographic projection of the connection through-hole F on the substrate 10 is equal to or approaching 5 μm, it is possible to both alleviate the problem of GDS defect, and meet the requirements of the layout of the array substrate 100.

By way of example, the minimum distance between the orthographic projection of the conductive connection portion 64 on the substrate 10 and the orthographic projection of the connection through-hole F on the substrate 10 is substantially 3 μm, 3.5 μm, 4 μm, 4.5 μm or 5 μm, and the present disclosure is not limited thereto.

An example is made in which the minimum distance between the orthographic projection of the conductive connection portion 64 on the substrate 10 and the orthographic projection of the connection through-hole F on the substrate 10 is substantially 3 μm, it is possible to both alleviate the problem of GDS defect, and meet the requirements of the layout of the array substrate 100.

It will be noted that due to the existence of certain uncontrollable errors (such as manufacturing process errors, equipment accuracy, or measurement errors), if the minimum distance between the orthographic projection of the conductive connection portion 64 on the substrate 10 and the orthographic projection of the connection through-hole F on the substrate 10 fluctuates within a range of 10%×3 μm, it is also possible to consider that the minimum distance between the orthographic projection of the conductive connection portion 64 on the substrate 10 and the orthographic projection of the connection through-hole F on the substrate 10 meets the requirement of being equal to 3 μm.

Based on the above, the driving circuit layer 20 in the array substrate 100 provided in the embodiments of the present disclosure further includes a constant-voltage conductive ring 40. The constant-voltage conductive ring 40 is located in the hole-peripheral region S1 and arranged around the hole-opening region W2.

With such an arrangement, as shown in combination with FIG. 4 and FIG. 9, the constant-voltage conductive ring 40 is of a closed figure, and the constant-voltage conductive ring 40 is disposed between the hole-opening region W2 and the display region AA, so as to utilize the constant-voltage conductive ring 40 to absorb the static electricity on the driving circuit layer 20 on the side of the display region AA proximate to the hole-opening region W2, and disperse the static electricity. In this way, the constant-voltage conductive ring 40 may be used to prevent the static electricity from accumulating too much energy at a certain position, thereby improving the quality of the array substrate 100.

In some embodiments, the constant-voltage conductive ring 40 is electrically connected to the bottom shielding layer 60. This means that multiple shielding patterns 61, which are arranged around the edge of the hole-opening region W2, may be connected in series by using the constant-voltage conductive ring 40 of a ring-shape. As a result, the concave-convex structures formed by the multiple shielding patterns 61 arranged around the edge of the hole-opening region W2 can be destroyed by using the constant-voltage conductive ring 40. In this way, the static electricity concentrated on the side of these shielding patterns 61 proximate to the hole-opening region W2 can be dispersed to the constant-voltage conductive ring 40 to alleviate the problem of the tip discharge on the side of these shielding patterns 61 proximate to the hole-opening region W2, which is conducive to the improvement of the quality of the array substrate 100.

In some examples, the constant-voltage conductive ring 40 is in a same layer as the bottom shielding layer 60, to enable the constant-voltage conductive ring 40 to be in contact with and connected to the bottom shielding layer 60.

With such an arrangement, no other conductive structure is required to be electrically connected the constant-voltage conductive ring 40 and the bottom shielding layer 60, which may simplify the wiring layout of the array substrate 100. Furthermore, since the constant-voltage conductive ring 40 and the bottom shielding layer 60 are in the same layer, the constant-voltage conductive ring 40 and the bottom shielding layer 60 can be formed by one patterning process, which is beneficial to simplifying the process of the array substrate 100.

It will be noted that the “same layer” refers to a layer structure formed by forming a film layer for forming specific patterns through a same film forming process and then performing a single patterning process using a same mask. Depending on different specific patterns, the patterning process may include exposure processes, development processes or etching processes, the specific patterns in the formed layer structure may be continuous or discontinuous, and these specific patterns may also be at different heights or have different thicknesses.

In some examples, the constant-voltage conductive ring 40 is electrically connected to the bottom shielding layer 60, and the first power supply signal line may be set to be connected to the constant-voltage conductive ring 40 through a via-hole, so as to enable the first power supply signal line to transmit the first power supply signal to the constant-voltage conductive ring 40 and the bottom shielding layer 60.

Here, a first portion of the constant-voltage conductive ring 40 is electrically connected to the first power supply signal line through the via-hole. A ring-width of the first portion of the constant-voltage conductive ring 40 may be increased. The ring-width of the first portion of the constant-voltage conductive ring 40 is set to be greater than ring-widths of the constant-voltage conductive ring 40 at other positions, which is convenient to realize the electrical connection between the constant-voltage conductive ring 40 and the first power supply signal line through the via-hole.

In some examples, the ring-width of the constant-voltage conductive ring 40 is in a range of 8 μm to 20 μm, inclusive.

In a case where the ring-width of the constant-voltage conductive ring 40 is equal to or approaching 8 μm, the ring-width of the constant-voltage conductive ring 40 is relatively small, which may reduce the space occupied by the constant-voltage conductive ring 40 in the hole-peripheral region S1, facilitating the reduction of the area of the hole-peripheral region S1. Furthermore, the constant-voltage conductive ring 40 may also be used to connect multiple shielding patterns 61 arranged around the edge of the hole-opening region W2 in series, alleviating the problem of the tip discharge on the side of these shielding patterns 61 proximate to the hole-opening region W2.

In a case where the ring-width of the constant-voltage conductive ring 40 is equal to or approaching 20 μm, the ring-width of the constant-voltage conductive ring 40 is relatively large, which may firmly multiple shielding patterns 61 arranged around the edge of the hole-opening region W2 in series, so as to connect the concave-convex structures formed by these shielding patterns 61 in series into a closed figure. In this way, the problem of the tip discharge on the side of these shielding patterns 61 proximate to the hole-opening region W2 is alleviated. Furthermore, the constant-voltage conductive ring 40 may also meet the size requirements of the hole-peripheral region S1.

In some other examples, the ring-width of the constant-voltage conductive ring 40 is in a range of 10 μm to 20 μm, inclusive.

In a case where the ring-width of the constant-voltage conductive ring 40 is in the range of 10 μm to 20 μm, the constant-voltage conductive ring 40 may both alleviate the problem that static electricity breakdown tends to occur on the side of the display region AA proximate to the hole-opening region W2, and meet the size requirements of the hole-peripheral region S1.

By way of example, the ring-width of the constant-voltage conductive ring 40 is substantially 10 μm, 12 μm, 15 μm, 18 μm or 20 μm. However, the present disclosure is not limited to the ring-width of the constant-voltage conductive ring 40.

An example is made in which the ring-width of the constant-voltage conductive ring 40 is substantially 10 μm, and the constant-voltage conductive ring 40, in this case, may both alleviate the problem that static electricity breakdown tends to occur on the side of the display region AA proximate to the hole-opening region W2, and meet the size requirements of the hole-peripheral region S1.

It will be noted that due to the existence of certain uncontrollable errors (such as manufacturing process errors, equipment accuracy, or measurement errors), if the ring-width of the constant-voltage conductive ring 40 fluctuates within a range of 10%×10 μm, it is also possible to consider that the ring-width of the constant-voltage conductive ring 40 meets the requirement of being equal to 10 μm.

Furthermore, the inventors have found through research that as shown in FIG. 4, the addition of the constant-voltage conductive ring 40 in the array substrate 100 will result in different loads for the plurality of target signal lines 30A. Then, the signals provided by the target signal lines 30A for transmission will be affected, thereby influencing output signals of pixel driving circuits Q electrically connected thereto, influencing the brightness of light-emitting devices O (shown in FIG. 3) in the display panel 200, and reducing the display effect of the display panel 200 (shown in FIG. 3).

As shown in combination with FIG. 4 to FIG. 8, the winding portions L2 of the plurality of target signal lines 30A are all located in the hole-peripheral region S1 and are arranged around the hole-opening region W2. Starting points of the winding portions L2 of the target signal line 30A are different, so in multiple winding portions L2 at a position of M3 in the hole-peripheral region S1, the farther away from the hole-opening region W2 a winding portion L2 is, the greater the degree to which the winding portion L2 bends, which will cause a structure composed of the multiple winding portions L2 to be not in a shape of a regular circle. That is, the structure composed of the multiple winding portions L2 may be in a shape of an ellipse. However, since the constant-voltage conductive ring 40 is disposed around the hole-opening region W2, the constant-voltage conductive ring 40 is generally in a shape of a circle.

As a result, the multiple winding portions L2 at the position of N3 in the hole-peripheral region S1 will protrude from the constant-voltage conductive ring 40. Thus, it will cause overlapping regions formed by orthographic projections of the multiple target signal lines 30A on the substrate 10 and the orthographic projection of the constant-voltage conductive ring 40 on the substrate 10 to have different areas, resulting in different loads for the different target signal lines 30A.

At the position of the hole-peripheral region S1 as shown in FIG. 6 and FIG. 7, the orthographic projection of the constant-voltage conductive ring 40 on the substrate 10 overlaps orthographic projections of lead portions L1 of some target signal lines 30A on the substrate 10, and the area of a region formed by overlapping is substantially the product of the width of the constant-voltage conductive ring 40 in a direction in which a lead portion L1 extends and a line-width of the lead portion L1 in a direction in which these lead portions L1 are arranged. And at the position of the hole-peripheral region S1 shown in FIG. 8, the orthographic projection of the constant-voltage conductive ring 40 on the substrate 10 overlaps orthographic projections of winding portions L2 of other some target signal lines 30A on the substrate 10, and areas of regions formed by overlapping are not the same.

At the position of the hole-peripheral region S1 shown in FIG. 6 and FIG. 7, the areas of the overlapping regions formed by the orthographic projection of the constant-voltage conductive ring 40 on the substrate 10 and the orthographic projections of the target signal lines 30A on the substrate 10 are substantially the same, however, the areas of the overlapping regions formed by the orthographic projection of the constant-voltage conductive ring 40 on the substrate 10 and the orthographic projections of the target signal lines 30A on the substrate 10 at the position of the hole-peripheral region S1 shown in FIG. 6 and FIG. 7 are obviously not equal to that at the position of the hole-peripheral region S1 shown in FIG. 8. Furthermore, at the position of the hole-peripheral region S1 shown in FIG. 8, the areas of the overlapping regions formed by the orthographic projection of the constant-voltage conductive ring 40 on the substrate 10 and the orthographic projections of the plurality of target signal lines 30A on the substrate 10 are also not the same.

It can be seen that the orthographic projection of the constant-voltage conductive ring 40 on the substrate 10 not only has different overlapping areas with winding portions L2 at a position of a certain region, but also has different overlapping areas with winding portions L2 at positions of various regions. As a result, parasitic capacitances formed by the constant-voltage conductive ring 40 and different target signal lines 30A are different, resulting in different loads on different target signal lines 30A, which affects the signal provided by the target signal line 30A for transmission and reduces the display effect of the display panel 200 (as shown in FIG. 3).

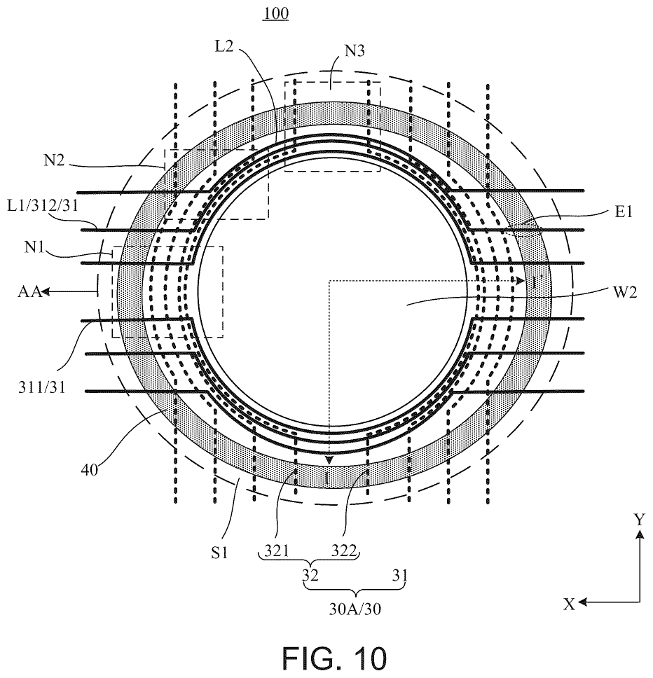

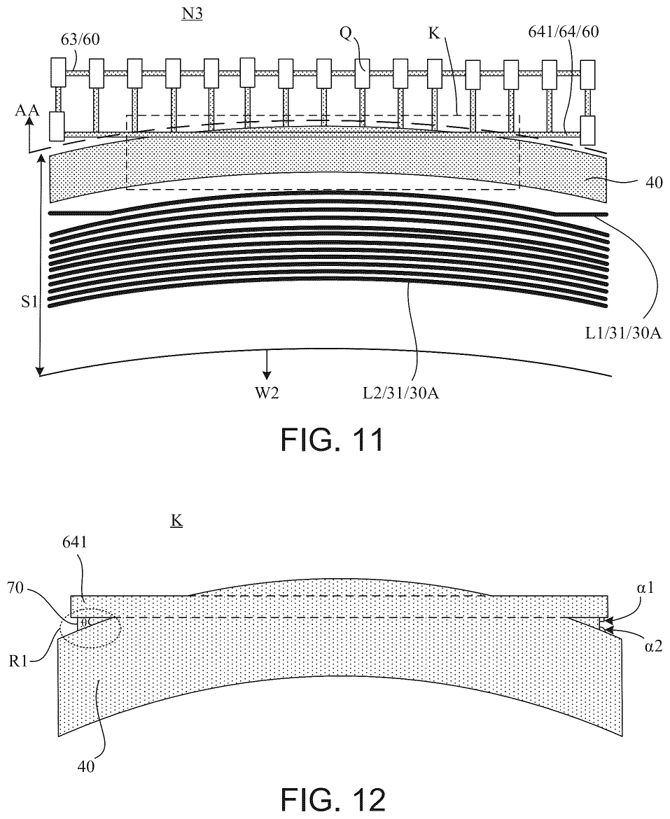

FIG. 10 is a structural diagram of an array substrate in accordance with some embodiments, and FIG. 11 is a partially enlarged view of the region N3 in FIG. 10. Here, the enlarged view at a position of N1 in FIG. 10 can be referred to the structure of M1 in FIG. 4 shown in FIG. 6, and the enlarged view at a position of N2 in FIG. 10 can be referred to the structure of M2 in FIG. 4 shown in FIG. 7.

Based on the above, in the array substrate 100 provided in the embodiments of the present disclosure, as shown in combination with FIG. 10 and FIG. 11, and as shown in combination with FIG. 6 and FIG. 7, it is arranged that along a direction from the display region AA to the hole-opening region W2, an orthographic projection of the winding portion L2 on the substrate 10 is located between an orthographic projection of the constant-voltage conductive ring 40 on the substrate 10 and the hole-opening region W2.

The above is equivalent to adjusting a shape of the constant-voltage conductive ring 40 to enable the shape of the constant-voltage conductive ring 40 to correspond to a shape of a structure composed of a plurality of winding portions L2, so that the constant-voltage conductive ring 40 avoids the plurality of winding portions L2, realizing the constant-voltage conductive ring 40 being disposed around an edge of the structure composed of the plurality of winding portions L2. For example, if the shape of the structure composed of the plurality of winding portions L2 is substantially an ellipse, the shape of the constant-voltage conductive ring 40 may also be an elliptical ring. It will be noted that the “elliptical ring” may be a hollowed-ellipse.

Furthermore, the orthographic projection of the constant-voltage conductive ring 40 on the substrate 10 may be made to be non-overlapping with the orthographic projection of the winding portion L2 on the substrate 10, and the orthographic projection of the constant-voltage conductive ring 40 on the substrate 10 may be made to overlap the orthographic projection of the lead portion L1 on the substrate 10.

Thus, the difference in areas of overlapping regions formed by the orthographic projections of the plurality of winding portions L2 on the substrate 10 and the orthographic projection of the constant-voltage conductive ring 40 on the substrate 10 may be alleviated to reduce the difference in parasitic capacitance formed between the plurality of target signal lines 30A and the constant-voltage conductive ring 40. Therefore, the problem of different loads of the plurality of target signal lines 30A is solved, to improve the display effect of the display panel 200.

In summary, the constant-voltage conductive ring 40 is added into the driving circuit layer 20 of the array substrate 100 in the present disclosure to alleviate the problem of the static electricity accumulated on the side of the display region AA of the array substrate 100 proximate to the hole-opening region W2 by using the constant-voltage conductive ring 40, so as to improve the quality of the array substrate 100. In addition, the constant-voltage conductive ring 40 is disposed along the edge of the structure composed of the plurality of winding portions L2, to enable the winding portions L2 to be located between the constant-voltage conductive ring 40 and the hole-opening region W2. In this way, the problem of different loads on plurality target signal lines 30A caused by the difference in areas of the overlapping regions formed by the orthographic projections of the plurality winding portions L2 on the substrate 10 and the orthographic projection of the constant-voltage conductive ring 40 on the substrate 10 may be alleviated, thereby facilitating the improvement of the display effect of the display panel 200.

In some embodiments, as shown in combination with FIG. 10 and FIG. 11, and as shown in combination with FIG. 6 and FIG. 7, a portion of the lead portion L1 whose orthographic projection on the substrate 10 overlaps the orthographic projection of the constant-voltage conductive ring 40 on the substrate 10 is a first overlapping portion E1. Areas of first overlapping portions E1 of a plurality of lead portions L1 are substantially equal. Here, the areas of the first overlapping portions E1 of the plurality of lead portions L1 may be understood as areas of orthographic projections of these first overlapping portions E1 on the substrate 10.

In a case where the orthographic projection of the constant-voltage conductive ring 40 on the substrate 10 is non-overlapping with the orthographic projection of the winding portion L2 on the substrate 10, and the orthographic projection of the constant-voltage conductive ring 40 on the substrate 10 overlaps the orthographic projection of the lead portion L1 on the substrate 10, the area of a region formed by overlapping of the orthographic projection of the constant-voltage conductive ring 40 on the substrate and the orthographic projection of the lead portion L1 of the target signal line 30A on the substrate 10 is substantially the product of the width of the constant-voltage conductive ring 40 in a direction in which the lead portion L1 extends and a line-width of the lead portion L1 in a direction in which the plurality of lead portions L1 are arranged.

The width of the constant-voltage conductive ring 40 in the direction in which the lead portion L1 extends is substantially equal to the ring-width of the constant-voltage conductive ring 40. That is, the area of a region formed by overlapping of the orthographic projection of the constant-voltage conductive ring 40 on the substrate 10 and an orthographic projection of a lead portion L1 of each target signal line 30A on the substrate 10 is substantially the product of the ring-width of the constant-voltage conductive ring 40 and the line-width of the lead portion L1.

Based on the above, the areas of the first overlapping portions E1 of the plurality of lead portions L1 are substantially equal to the product of the ring-width of the constant-voltage conductive ring 40 and the line-width of the lead portion L1. Since the ring-width of the constant-voltage conductive ring 40 and the line-width of the lead portion L1 are constant, it can be achieved that the areas of the first overlapping portions E1 of the plurality of lead portions L1 are substantially equal.

Furthermore, the parasitic capacitances formed between the plurality of target signal lines 30A and the constant-voltage conductive ring 40 can be made substantially equal, to realize that the loads of the plurality of target signal lines 30A are substantially equal, which is conducive to improving the display effect of the display panel 200.

It will be noted that due to the existence of certain uncontrollable errors (such as manufacturing process errors, equipment accuracy, or measurement errors), if a difference between areas of first overlapping portions E1 of any two lead portions L1 fluctuates within 10% of the area of a first overlapping portion E1 of any one of the two lead portions L1, it is also possible to consider that the areas of the first overlapping portions E1 of the two lead portions L1 meets the requirement of equivalence.

In a case where the shape of the constant-voltage conductive ring 40 is adjusted to enable the orthographic projection of the constant-voltage conductive ring 40 on the substrate 10 to be non-overlapping with the orthographic projection of the winding portion L2 on the substrate 10, and the orthographic projection of the constant-voltage conductive ring 40 on the substrate 10 to overlap the orthographic projection of the lead portion L1 on the substrate 10, a size of the adjusted constant-voltage conductive ring 40 will be increased to a certain extent. As shown in FIG. 9, it is equivalent to stretching the constant-voltage conductive ring 40 along the second direction Y.

FIG. 12 is a partially enlarged view of the region K in FIG. 11, which illustrates first conductive connection portions 641 and the constant-voltage conductive ring 40 at a position of K in FIG. 11, so as to clearly show how the first conductive connection portions 641 and the constant-voltage conductive ring 40 are connected.

Based on the above, in some embodiments, as shown in combination with FIG. 11 and FIG. 12, the conductive connection portions 64 and the constant-voltage conductive ring 40 are in a same layer. A conductive connection portion 64 includes first conductive connection portions 641, and a first conductive connection portion 641 intersects the constant-voltage conductive ring 40 to achieve connection between the conductive connection portion 64 and the constant-voltage conductive ring 40.

With such an arrangement may reduce the space occupied by the conductive connection portion 64 and the constant-voltage conductive ring 40 in the hole-peripheral region S1. This is beneficial to reducing a distance between the constant-voltage conductive ring and the shielding pattern 61 (as shown in FIG. 9). Furthermore, it is beneficial to reduce a distance between the constant-voltage conductive ring and the display region AA, which is convenient to reduce the size of the hole-peripheral region S1.

However, the first conductive connection portion 641 intersects the constant-voltage conductive ring 40, forming a first acute angle θ, and the first conductive connection portion 641 intersects the constant-voltage conductive ring 40, forming a first space R1.

The inventors have found through research that the problem of the tip discharge is likely to occur between the first conductive connection portion 641 and the constant-voltage conductive ring 40 in the first space R1. Specifically, the conductive connection portion 64 and the constant-voltage conductive ring 40 are in the same layer, the conductive connection portion 64 and the constant-voltage conductive ring 40 are of an integrated design, and the first conductive connection portion 641 intersects the constant-voltage conductive ring 40 to form the first acute angle E, so a tip structure will be formed in the corresponding first space R1. Due to the existence of the tip structure, static electricity on the conductive connection portion 64 and the constant-voltage conductive ring 40 will be concentrated on the tip structure, which may easily lead to the problem of the tip discharge in the first space R1.

In light of this, as shown in combination with FIG. 11 and FIG. 12, the driving circuit layer 20 may be configured to further include first compensation portions 70, and the first compensation portions 70 and the constant-voltage conductive ring 40 are in the same layer. A first compensation portion 70 is located in the first space R1, and the first compensation portion 70 intersects the first conductive connection portion 641 to form a first included angle α1, and the first compensation portion 70 intersects the constant-voltage conductive ring 40 to form a second included angle α2 where the first included angle α1 and the second included angle α2 are both greater than or equal to 90°.

As in the above structure, the first compensation portion 70 is added into the driving circuit layer 20 in the same layer as the conductive connection portion 64 and the constant-voltage conductive ring 40, and the first compensation portion 70 is utilized to fill the first space R1. That is, the first compensation portion 70 is filled at a position of the tip structure in the first space R1 to destroy the tip structure formed by the intersection of the first conductive connection portion 641 and the constant-voltage conductive ring 40. Based on this, the first compensation portion 70 can be used to alleviate the problem of the tip discharge in the first space R1.

In some examples, the first compensation portion 70 may have a triangle-like shape. The “triangle-like shape” can be understood that an edge of the triangle-like shape adjacent to the first conductive connection portion 641 form a fit with an edge of the first conductive connection portion 641. That is, the edge of the triangle-like shape adjacent to the first conductive connection portion 641 and the edge of the first conductive connection portion 641 may be completely fitted. Moreover, an edge of the triangle-like shape adjacent to the constant-voltage conductive ring 40 forms a fit with an edge of the constant-voltage conductive ring 40. That is, the edge of the triangle-like shape adjacent to the constant-voltage conductive ring 40 and the edge of the constant-voltage conductive ring 40 may be completely fitted.

In some examples, a length of the first compensation portion 70 along a circumferential direction of the constant-voltage conductive ring 40 is in a range of 2.5 μm to 20 μm, inclusive.

In a case where the length of the first compensation portion 70 is in the range of 2.5 μm to 20 μm, the first compensation portion 70 may both fill the position of the tip structure in the first space R1 and destroy the tip structure formed by the intersection of the first conductive connection portion 641 and the constant-voltage conductive ring 40 to ameliorate the problem of the tip discharge occurring in the first space R1, and also prevent the first compensation portion 70 from having an excessively long length, which would lead to the problem of taking up too much space on the array substrate 100, reducing the flexibility of layout of the array substrate 100.

In some other examples, a length of the first compensation portion 70 along a circumferential direction of the constant-voltage conductive ring 40 is in a range of 5 μm to 10 μm, inclusive.

In a case where the length of the first compensation portion 70 is in the range of 5 μm to 10 μm, the first compensation portion 70 may both ameliorate the problem of the tip discharge occurring in the first space R1 and meet the requirements of layout of the array substrate 100.

By way of example, the length of the first compensation portion 70 is approximately any one of 2.5 μm, 4 μm, 5 μm, 8 μm, 10 μm, 15 μm, 18 μm, and 20 μm. However, the present disclosure is not limited thereto.

An example is made in which the length of the first compensation portion 70 is approximately 5 μm, the first compensation portion 70, in this case, may not only ameliorate the problem of the tip discharge in the first space R1, but also meet the requirements of layout of the array substrate 100.

It will be noted that due to the existence of certain uncontrollable errors (such as manufacturing process errors, equipment accuracy, or measurement errors), if the length of the first compensation portion 70 fluctuates within a range of 10%×5 μm, it is also possible to consider that the length of the first compensation portion 70 meets the requirement of being equal to 5 μm.

In some other embodiments, a first conductive connection portion 641 and the constant-voltage conductive ring 40 may be disposed in a direct contact connection at ends. That is, an edge of the first conductive connection portion 641 at a side thereof proximate to the hole-opening region W2 is in contact connection with an edge of the constant-voltage conductive ring 40 at a side thereof away from the hole-opening region W2.

In this case, the conductive connection portion 64 and the constant-voltage conductive ring 40 will not form a relatively obvious tip structure therebetween, which may prevent the problem of static electricity breakdown at the joint position of the conductive connection portion 64 and the constant-voltage conductive ring 40.

In yet some other embodiments, in a case where the hole-peripheral region S1 has sufficient space, an end of the conductive connection portion 64 proximate to the hole-opening region W2 may be disposed to directly contact and connect to the constant-voltage conductive ring 40.

In this case, the conductive connection portion 64 and the constant-voltage conductive ring 40 will not form a relatively obvious tip structure therebetween, which may prevent the problem of static electricity breakdown at the joint position of the conductive connection portion 64 and the constant-voltage conductive ring 40.

The above mainly introduces the structures of the constant-voltage conductive ring 40 and the bottom shielding layer 60. The following will introduce the types of the plurality of target signal lines 30A and how to lay them out in the hole-peripheral region S1 in combination with the relevant drawings.

In some embodiments, as shown in FIG. 10, since the winding portions L2 of the plurality of target signal lines 30A all surround the hole-opening region W2 and are located in the hole-peripheral region S1, if the winding portions L2 of the plurality of target signal lines 30A are all arranged in a portion of the hole-peripheral region S1 located on one side of the hole-opening region W2, the size of the hole-peripheral region S1 will be increased, thereby reducing the display effect of the display panel 200.

In light of this, the plurality of target signal lines 30A may be divided into target signal lines of a first part and target signal lines of a second part. Along a direction in which the plurality of first signal lines 30A are arranged, lead portions L2 of the signal lines of the first part and lead portions L2 of the signal lines of the second part are located at two sides of the hole-opening region W2, respectively.

With such an arrangement, the winding portions L2 of the plurality of target signal lines 30A can be dispersed in portions of the hole-peripheral regions S1 on two sides of the hole-opening region W2 to prevent an excessive number of winding portions L2 in a portion of the hole-peripheral region S1 on one side of the hole-opening region W2, which is beneficial to reducing the size of the hole-peripheral region S1 and improving the display effect of the display panel 200.

In some embodiments, as shown in FIG. 10, the plurality of target signal lines 30A include a plurality of first signal lines 31, and lead portions L1 of the plurality of first signal lines 31 extend along the first direction X and are arranged in the second direction Y.

The plurality of first signal lines 31 in the plurality of target signal lines 30A may be divided into signal lines 311 of a first part and signal lines 312 of a second part. Along the second direction Y winding portions L2 of the signal lines 311 of the first part and winding portions L2 of the signal lines 312 of the second part are arranged in portions of the hole-peripheral region S1 on two sides of the hole-opening region W2, respectively.

Based on the above, the winding portions L2 of the plurality of first signal lines 31 corresponding to the hole-opening region W2 can be dispersed in the portions of the hole-peripheral region S1 on two sides of the hole-opening region W2, which is beneficial to reducing the size of the hole-peripheral region S1.

In some examples, the number of the signal lines 311 of the first part and the number of the signal lines 312 of the second part are substantially equal.

With such an arrangement, the winding portions L2 of the plurality of first signal lines 31 in the plurality of target signal lines 30A can be evenly distributed in the portions of the hole-peripheral regions S1 located on two sides of the hole-opening region W2, which not only facilitates the layout of the winding portions L2 in the hole-peripheral region S1, but also facilitates further reducing the size of the hole-peripheral region S1, thereby improving the display effect of the display panel.

It will be noted that since the number of the plurality of first signal lines 31 is not necessarily an even number, or due to the existence of certain uncontrollable errors (such as manufacturing process errors, equipment accuracy, or measurement errors), if the difference between the number of the signal lines 311 of the first part and the number of the signal lines 312 of the second part fluctuates within a range of 10% of the total number of the signal lines 311 of the first part or the total number of the signal lines 312 of the second part, it is also possible to consider that the number of the signal lines 311 of the first part and the number of the signal lines 312 of the second part meets the requirement of equivalence.

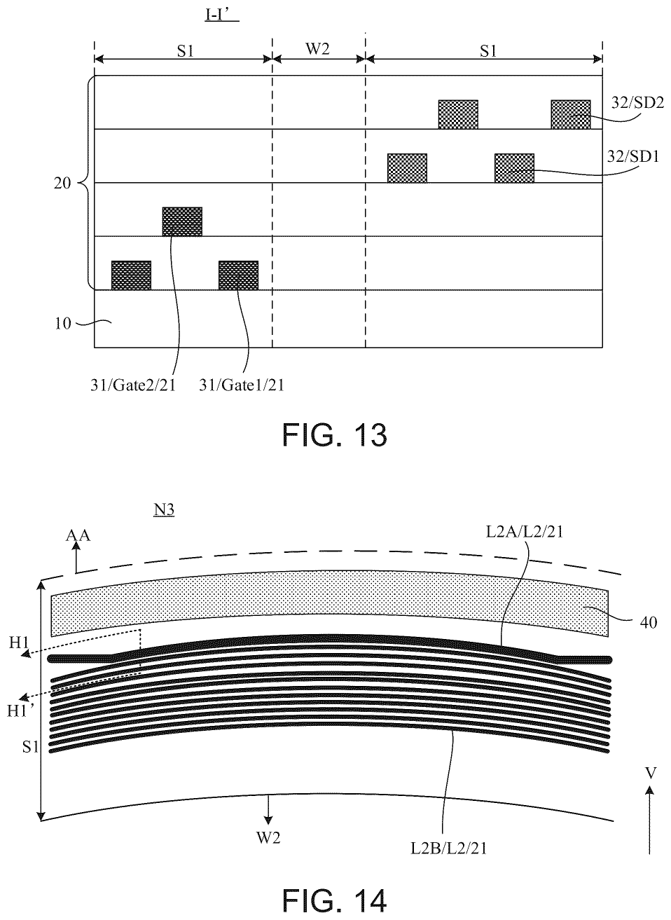

FIG. 13 is a sectional view taken along the line 14 in FIG. 10.

In some embodiments, as shown in combination with FIG. 10 and FIG. 13, the driving circuit layer 20 includes multiple metal conductive layers 21 stacked on the substrate 10. Along a direction away from the substrate 10, the multiple metal conductive layers 21 are a first gate metal layer Gate1, a second gate metal layer Gate2, a first wiring metal layer SD1, and a second wiring metal layer SD2.

The first gate metal layer Gate1 may be set to include a portion of the plurality of first signal lines 31, and the second gate metal layer Gate2 may be set to include the other portion of the plurality of first signal lines 31.

That is, the plurality of first signal lines 31 are dispersedly formed in different metal conductive layers 21. Based on this, the problem of easy short circuit due to the limited space in the hole-peripheral region S1 in a case where the plurality of first signal lines 31 are all located in a same layer can be prevented. That is, it is beneficial to the layout of the first signal lines 31 in the hole-peripheral region S1, thereby improving the quality of the array substrate 100. In addition, such an arrangement may also reduce the space occupied by the winding portions L2 of the plurality of target signal lines 30A in the hole-peripheral region S1, thereby reducing the size of the hole-peripheral region S1.

In some examples, in a case where the multiple metal conductive layers 21 further include a third metal layer, the plurality of first signal lines 31 may be disposed separately in the first gate metal layer Gate1, the second gate metal layer Gate2, and the third metal layer, so as to better to lay out the first signal lines 31 to reduce the size of the hole-peripheral area S1.

In some examples, along the second direction, in two first signal lines 31, whose orthographic projections on the substrate 10 are adjacent to each other, one first signal line 31 is located in the first gate metal layer Gate1, and the other first signal line 31 is located in the second gate metal layer Gate2.

With such an arrangement, a distance between two adjacent first signal lines 31 in a same metal conductive layer 21 can be increased, so as to prevent the problem of short circuit between the two adjacent first signal lines 31 in the same metal conductive layer 21. Furthermore, since the distance between two adjacent first signal lines 31 in the same metal conductive layer 21 is increased, the mutual crosstalk between the two first signal lines 31 may be reduced, thereby improving the quality of the array substrate 100.

In some examples, on the basis of dispersedly forming the plurality of first signal lines 31 in different metal conductive layers 21, orthographic projections of the two adjacent first signal lines 31 on the substrate 10 have a gap therebetween.

The above arrangement is equivalent to staggering first signal lines 31 located in different metal conductive layers 21, which may increase a distance between two first signal lines 31, whose orthographic projections on the substrate 10 are adjacent to each other, along the second direction, so as to reduce the mutual crosstalk between the two first signal lines 31, and improve the quality of the array substrate 100.

In some embodiments, as shown in FIG. 10, the plurality of target signal lines 30A include a plurality of second signal lines 32, and lead portions L1 of the plurality of second signal lines 32 extend along the second direction Y and are arranged in the first direction X.

The plurality of second signal lines 32 may be divided into signal lines 321 of a third part and signal lines 322 of a fourth part. Along the first direction X, winding portions L2 of the signal lines 321 of the third part and winding portions L2 of the signal lines 322 of the fourth part are arranged in portions of the hole-peripheral region S1 on two sides of the hole-opening region W2, respectively.

Based on the above, the winding portions L2 of the plurality of second signal lines 32 can be dispersed in the portions of the hole-peripheral region S1 on two sides of the hole-opening region W2, which is beneficial to reducing the size of the hole-peripheral region S1.

In some examples, the number of the signal lines 321 of the third part and the number of the signal lines 322 of the fourth part are substantially equal.

With such an arrangement, the winding portions L2 of the plurality of second signal lines 32 in the plurality of target signal lines 30A can be evenly distributed in the portions of the hole-peripheral regions S1 located on two sides of the hole-opening region W2, which not only facilitates the layout of the winding portions L2 in the hole-peripheral region S1, but also facilitates further reducing the size of the hole-peripheral region S1, thereby improving the display effect of the display panel.

It will be noted that since the number of the plurality of second signal lines 32 is not necessarily an even number, or due to the existence of certain uncontrollable errors (such as manufacturing process errors, equipment accuracy, or measurement errors), if the difference between the number of the signal lines 321 of the third part and the number of the signal lines 322 of the fourth part fluctuates within a range of 10% of the total number of the signal lines 321 of the third part or the total number of the signal lines 322 of the fourth part, it is also possible to consider that the number of the signal lines 321 of the third part and the number of the signal lines 322 of the fourth part meets the requirement of equivalence.

In some embodiments, as shown in combination with FIG. 10 and FIG. 13, the plurality of second signal lines 32 may be data signal lines, and the plurality of second signal lines 32 may all be located in the second wiring metal layer SD2. This case will result in the winding portions L2 of the plurality of second signal lines 32 all being located in a same layer, resulting in these winding portions L2 being arranged compactly within the hole-peripheral region S1, which is not only prone to the problem of two adjacent winding portions L2 crosstalk with each other, but also prone to the problem of shorted connection.

In light of this, the lead portions L1 of the plurality of second signal lines 32 may be all arranged in the second wiring metal layer SD2, while the winding portions L2 of the plurality of second signal lines 32 in the hole-peripheral region S1 may be arranged in different layers. For example, the first wiring metal layer SD1 may include winding portions L2 of a portion of plurality of the second signal lines 32, and the second wiring metal layer SD2 may include winding portions L2 of the other portion of plurality of the second signal lines 32.

In this way, the plurality of second signal lines 32 are respectively disposed in the multiple metal conductive layers 21, which is beneficial to the layout of the second signal lines 32 in the hole-peripheral region S1, preventing the problem of short circuit due to all the second signal lines 32 being located in the same layer. In addition, such an arrangement may also reduce the space occupied by the winding portions L2 of the plurality of target signal lines 30A in the hole-peripheral region S1, thereby reducing the size of the hole-peripheral region S1.

In some examples, along the first direction X, in two second signal lines 32, whose orthographic projections on the substrate 10 are adjacent to each other, one second signal line 32 is located in the first wiring metal layer SD1, and the other second signal line 32 is located in the second wiring metal layer SD2.

With such an arrangement, a distance between two adjacent second signal lines 32 in a same metal conductive layer 21 may be increased, so as to prevent the problem of short circuit between the two adjacent second signal lines 32 in the same metal conductive layer 21. Furthermore, since the distance between two adjacent second signal lines 32 in the same metal conductive layer 21 is increased, the mutual crosstalk between the two second signal lines 32 may be reduced, thereby improving the quality of the array substrate 100.

In some examples, on the basis of dispersedly forming the plurality of second signal lines 32 in different metal conductive layers 21, orthographic projections of the two adjacent second signal lines 32 on the substrate 10 have a gap therebetween.

The above arrangement is equivalent to staggering second signal lines 32 located in different metal conductive layers 21, which may increase a distance between two second signal lines 32, whose orthographic projections on the substrate are adjacent to each other, along the first direction, so as to reduce the mutual crosstalk between the two second signal lines 32, and improve the quality of the array substrate 100.

The above mainly introduces how to lay out the winding portions L2 of the plurality of target signal lines 30A in the hole-peripheral region S1. The following will introduce the design related to the structure of the winding portions L2 of the plurality of target signal lines 30A in combination with relevant drawings.

The inventors have found through research that a plurality of winding portions L2 are provided on a side of an outer winding portion L2A proximate to the hole-opening region W2, while no winding portion is provided on a side of the outer winding portion L2A proximate to the display region A. Furthermore, there is a blank region on the side of the outer winding portion L2A proximate to the display region AA. That is, a winding portion L2 whose orthographic projection on the substrate 10 is furthest away from the hole-opening region W2 is the outer winding portion L2A.

Based on this, when the plurality of winding portions L2 are formed by means of etching, due to different densities and numbers of winding portions L2 arranged on both sides of the outer winding portion L2A, this can lead to a loading effect during the etching process, which results in uneven development and uneven etching, with more etching at a place where the loading is small, resulting in a smaller line-width or even broken lines. That is, the outer winding portion L2A is prone to the problem of smaller line-width or even broken lines due to the obvious difference in pattern density at both sides of the outer winding portion L2A.

FIG. 14 is another partially enlarged view of the region N3 in FIG. 10, and FIG. is a sectional view taken along the line H1-H1′ in FIG. 14.

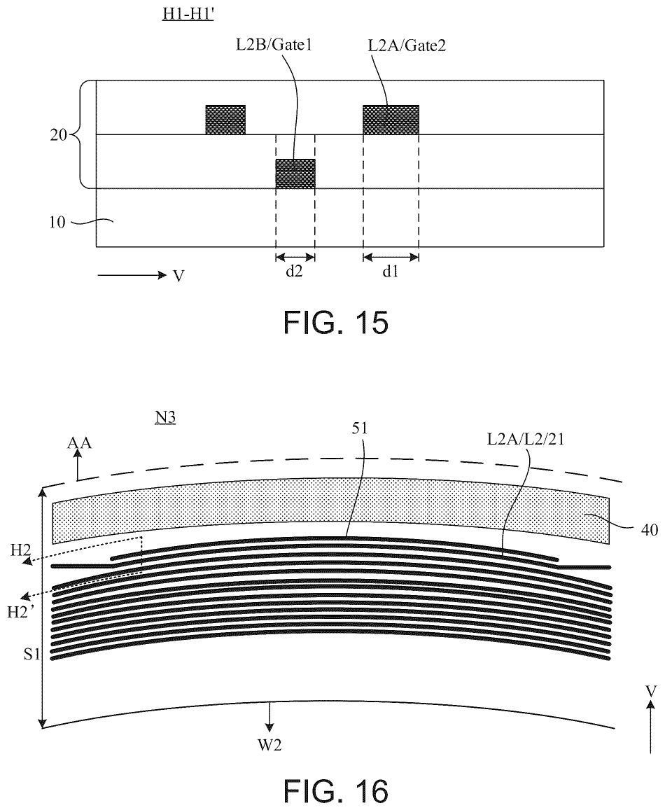

In light of the above, in some embodiments, as shown in combination with FIG. 14 and FIG. 15, a winding portion L2 in the plurality of winding portions L2 whose orthographic projection on the substrate 10 is furthest away from the hole-opening region W2 is an outer winding portion L2A, and the rest of plurality of winding portions L2 are each a first inner winding portion L2B.

In a direction V from the hole-opening region W2 to the display region AA, a width of the outer winding portion L2A is d1, and a width of the first inner winding portion L2B is d2, where d1 is greater than d2.

The above is equivalent to widening the outer winding portion L2A, so as to use the widened portion of the outer winding portion L2A to compensate for the problem of a smaller line-width or even broken line of the outer winding portion L2A caused by different etching rates at both sides of the outer winding portion L2A, improving the quality of the array substrate 100.

In some examples, 1.1 times d2 is less than or equal to d1, and d1 is less than or equal to 1.15 times d2 (1.1d2≤d1≤1.15d2). That is, the outer winding portion L2A may be widened by 10% to 15% d2 to realize that the width d1 of the outer winding portion L2A meets a range of 1.1d2 to 1.15d2, inclusive. Based on this, when forming the first inner winding portion L2B with the width d2 and the outer winding portion L2A with the width d1, since an etching rate at a position of the outer winding portion L2A is faster than an etching rate at a position of the first inner winding portion L2B, the width of the outer winding portion L2A finally formed will be less than d1.

That is, the problem of different etching rates may be compensated by utilizing the width that is widened by 10% to 15% d2, so that the width of the outer winding portion L2A finally formed is approximately equal to the width d2 of the first inner winding portion L2B, and the problem of a smaller line-width or even a broken line of the outer winding portion L2A due to the difference in etching rates at both sides of the outer winding portion L2A may be prevented. In addition, widening the outer winding portion L2A by 10% to 15% d2 may also prevent the problem that the load of the outer winding portion L2A is different from the load of the first inner winding portion L2B due to a much large width of the outer winding portion L2A.

In some examples, d1 is approximately equal to 1.13d2.

In a case where the width d1 of the outer winding portion L2A is approximately equal to 1.13d2, the width widened by 13% d2 can be used to compensate for the problem of different etching rates, which makes the width of the outer winding portion L2A finally formed approximately equal to the width d2 of the first inner winding portion L2B, thereby alleviating the problem of a smaller line-width or even broken line of the outer winding portion L2A. In addition, the width of the outer winding portion L2A is possible to be prevented from being too large to affect the load. However, the embodiments of the present disclosure are not limited thereto.

By way of example, d1 is approximately equal to any one of d2, 1.1d2, 1.2d2, 1.3d2, 1.4d2, and 1.5d2.

By way of example, the width d2 of the first inner winding portion L2B is approximately 2.3 μm, and the width d1 of the outer winding portion L2A is approximately 2.6 μm.

In this case, the widening of the outer winding portion L2A may not only alleviate the problem of the smaller line-width or even broken line of the outer winding portion L2A, but also prevent the problem of different loads on the individual winding portions L2 from occurring.

The inventors have found through research that different densities and numbers of the winding portions L2 on both sides of the outer winding portion L2A will not only cause the outer winding portion L2A to be prone to the problem of the smaller line-width or even a broken line, but will also cause the load of the outer winding portion L2A to be different from the load of the other winding portions L2, which will affect the display effect of the display panel.

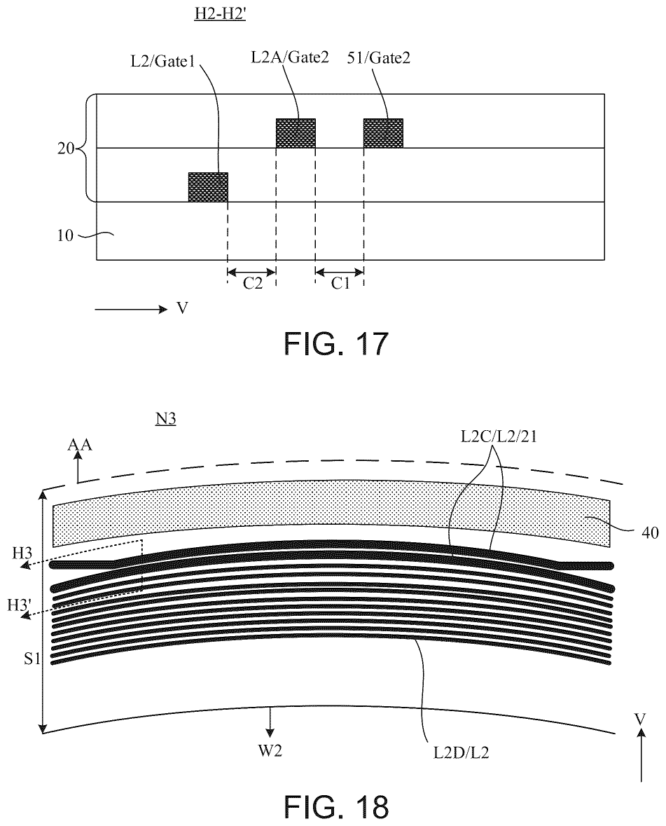

FIG. 16 is yet another partially enlarged view of the region N3 in FIG. 10, and FIG. 17 is a sectional view taken along the line H2-H2′ in FIG. 16.

In light of this, the above two problems may be alleviated simultaneously by another means in some embodiments. As shown in combination with FIG. 16 and FIG. 17, the driving circuit layer 20 further includes a dummy winding portion 51. The dummy winding portion 51 is located between the outer winding portion L2A and the display region AA, and is in a same layer as the outer winding portion L2A.

Here, regardless of whether the plurality of winding portions L2 are arranged in different layers or the same layer, only the outer winding portion L2A closest to the display region AA along the direction V from the hole-opening W2 to the display region AA is offered for the arrangement, in which the dummy winding portion 51 is disposed at a side of the outer winding portion L2A proximate to the display region AA, and the dummy winding portion 51 is in the same layer as the outer winding portion L2A.

As in the above structure, since the dummy winding portion 51 is in the same layer as the outer winding portion L2A, the dummy winding portion 51 can be used to balance the difference in the pattern density at both sides of the outer winding portion L2A, so as to prevent the problem of different etching rates at both sides of the outer winding portion L2A, and prevent the problem of the smaller line-width or even broken line of the outer winding portion L2A, improving the quality of the array substrate 100. Moreover, the dummy winding portion 51 can also be used to balance the difference between the load of the outer winding portion L2A and the load of the other winding portions L2, improving the display effect of the display panel.

In addition, the dummy winding portion 51 and the outer winding portion L2A are in the same layer, so that the dummy winding portion 51 and the outer winding portion L2A can be formed by one patterning process, which may simplify the process of the array substrate 100.

In some examples, the dummy winding portion 51 is located between the outer winding portion L2A and the constant-voltage conductive ring 40, so as to prevent the constant-voltage conductive ring 40 from affecting the load of the dummy winding portion 51 and thus the load of the outer winding portion L2A, which may again lead to the problem that the load of the outer winding portion L2A is different from the load of the other winding portions L2.

It will be noted that the “same layer” refers to a layer structure formed by forming a film layer for forming specific patterns through a same film forming process and then performing a single patterning process using a same mask. Depending on different specific patterns, the patterning process may include exposure processes, development processes or etching processes, the specific patterns in the formed layer structure may be continuous or discontinuous, and these specific patterns may also be at different heights or have different thicknesses.

In some embodiments, as shown in combination with FIG. 16 and FIG. 17, along the direction V from the hole-opening region W2 to the display region AA, a distance C1 between the dummy winding portion 51 and the outer winding portion L2A is set to be substantially equal to a distance C2 between any two adjacent winding portions L2, It may be convenient to simultaneously form the dummy winding portion 51 and the plurality of winding portions L2, thereby reducing the manufacturing difficulty of the array substrate 100. Furthermore, it may also be convenient to reduce the layout difficulty of the array substrate 100 and improve the regularity of the array substrate 100.

It will be noted that due to the existence of certain uncontrollable errors (such as manufacturing process errors, equipment accuracy, or measurement errors), if a difference between the distance C1 between the dummy winding portion 51 and the outer winding portion L2A and the distance C2 between any two adjacent winding portions L2 fluctuates within a range of 10% C1 or 10% C2, it is also possible to consider that the distance C1 between the dummy winding portion 51 and the outer winding portion L2A and the distance C2 between any two adjacent winding portions L2 meet the requirement of equivalence.

In some embodiments, as shown in combination with FIG. 16 and FIG. 17, in the direction V from the hole-opening region W2 to the display region AA, a width of the dummy winding portion 51 is equal to a width of the winding portion L2. It may be convenient to simultaneously form the dummy winding portion 51 and the plurality of winding portions L2, thereby reducing the manufacturing difficulty of the array substrate 100. Furthermore, it may also be convenient to reduce the layout difficulty of the array substrate 100 and improve the regularity of the array substrate 100.

In summary, the dummy winding portion 51 does not need to be electrically connected to the pixel driving circuit, and other specification parameters can be the same as those of the plurality of winding portions L2. It may be convenient to simultaneously form the dummy winding portion 51 and the plurality of winding portions L2, thereby reducing the manufacturing difficulty of the array substrate 100 and improving the regularity of the array substrate 100.

The inventors have found through research that the plurality of winding portions L2 will be arranged in different layers. Taking a case where the plurality of target signal lines 30A include a plurality of first signal lines 31 as an example, winding portions L2 of the plurality of first signal lines 31 are arranged in the first gate metal layer Gate1 and the second gate metal layer Gate2. Taking a case where the plurality of target signal lines 30A include a plurality of second signal lines 32 as an example, winding portions L2 of the plurality of second signal lines 32 are arranged in the first wiring metal layer SD1 and the second wiring metal layer SD2.

Based on the above, each metal conductive layer 21, which is provided therein with winding portions L2, has an edge winding portion L2C farthest away from the hole-opening region W2, A plurality of winding portions L2 are provided on a side of each edge winding portion L2C proximate to the hole-opening region W2, while no winding portion is provided on a side of each edge winding portion L2C proximate to the display region AA. Furthermore, there is a blank region on the side of each edge winding portion L2C proximate to the display region AA. That is, not only the outer winding portion L2A is prone to the problem of the smaller line-width or even broken line, but each edge winding portion L2C is also prone to the problem of the smaller line-width or even broken line.

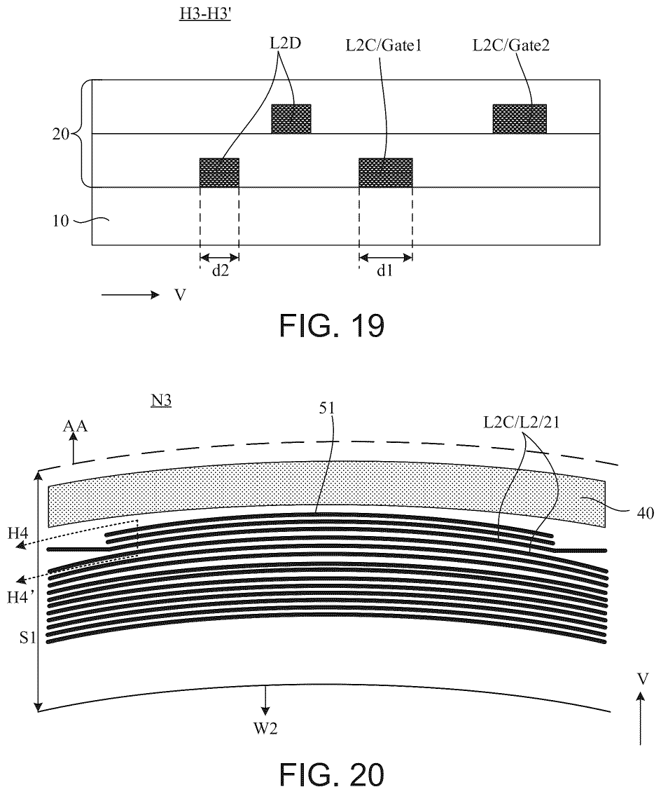

FIG. 18 is still another partially enlarged view of the region N3 in FIG. 10, and FIG. 19 is a sectional view taken along the line H3-H3′ in FIG. 18.

Based on the above, in some embodiments, as shown in combination with FIG. 18 and FIG. 19, in multiple winding portions L2 located in a same metal conductive layer 21, a winding portion L2 farthest from the hole-opening region W2 is an edge winding portion L2C, and the remaining winding portions L2 other than the edge winding portion L2C in the same layer are each a second inner winding portion L2D. In the direction V from the hole-opening region WV2 to the display region AA, a width of the edge winding portion L2C is d1, and a width of the second winding portion L2D is d2, where d1 is greater than d2

The difference from the array substrate 100 shown in FIG. 14 and FIG. 15 is that not only the outer winding portion L2A is widened, but also the edge winding portion L2C closest to the display region AA in each metal conductive layer 21 is widened.

With such an arrangement, the widened portion of the edge winding portion L2C can be used to compensate for the problem of a smaller line-width or even broken line of the edge winding portion L2C caused by different etching rates at both sides of the edge winding portion L2C, improving the quality of the array substrate 100.

In some examples, 1.1 times d2 is less than or equal to d1, and d1 is less than or equal to 1.15 times d2 (1.1d2≤d1≤1.15d2). That is, each edge winding portion L2C may be widened by 10% to 15% d2 to realize that the width d1 of each edge winding portion L2C meets a range of 1.1d2 to 1.15d2, inclusive. Based on this, when forming the second inner winding portion L2D with the width d2 and each edge winding portion L2C with the width d1 in the same metal conductive layer 21, since an etching rate at a position of the edge winding portion L2C is faster than an etching rate at a position of the second inner winding portion L2D, the width of each edge winding portion L2C finally formed will be less than d1.

That is, the problem of different etching rates may be compensated by utilizing the width that is widened by 10% to 15% d2, so that the width of each edge winding portion L2C finally formed is approximately equal to the width d2 of the second inner winding portion L2D arranged in the same layer, and the problem of the smaller line-width or even a broken line of each edge winding portion L2C due to the difference in etching rates at both sides of each edge winding portion L2C may be prevented.

In addition, widening each edge winding portion L2C by 10% to 15% d2 may also prevent the problem that the load of each edge winding portion L2C is different from the load of the second inner winding portion L2D arranged in the same layer due to a much large width of each edge winding portion L2C.

In some examples, d1 is approximately equal to 1.13d2.

In a case where each edge winding portion L2C is approximately equal to 1.13d2, the width widened by 13% d2 can be used to compensate for the problem of different etching rates, which makes the width of each edge winding portion L2C finally formed approximately equal to the width d2 of the second inner winding portion L2D, thereby alleviating the problem of a smaller line-width or even broken line of each edge winding portion L2C. In addition, the width of each edge winding portion L2C is possible to be prevented from being too large to affect the load. However, the embodiments of the present disclosure are not limited thereto.

By way of example, d1 is approximately equal to any one of d2, 1.1d2, 1.2d2, 1.3d2, 1.4d2, and 1.5d2.

By way of example, the width d2 of the second inner winding portion L2D is approximately 2.3 μm, and the width d1 of each edge winding portion L2C is approximately 2.6 μm.

In this case, the widening of each edge winding portion L2C may not only alleviate the problem of the smaller line-width or even broken line of each edge winding portion L2C, but also prevent the problem of different loads on the individual winding portions L2 from occurring.

The inventors have found through research that different densities and numbers of the winding portions L2 on both sides of each edge winding portion L2C will not only cause the edge winding portion L2C to be prone to the problem of the smaller line-width or even a broken line, but will also cause the load of the edge winding portion L2C to be different from the load of the other winding portions L2, which will affect the display effect of the display panel.

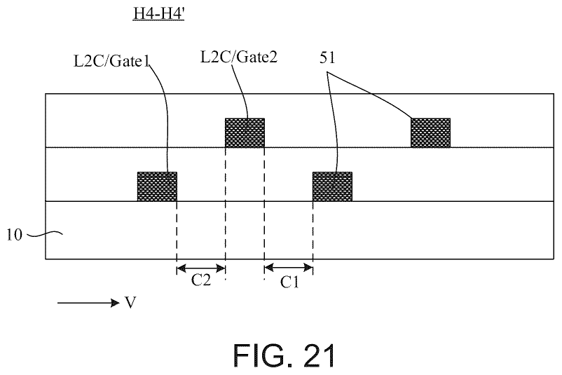

FIG. 20 is still yet another partially enlarged view of the region N3 in FIG. 10, and FIG. 21 is a sectional view taken along the line H4-H4′ in FIG. 20.

In light of this, the above two problems may be alleviated simultaneously by another means in some embodiments. As shown in combination with FIG. 20 and FIG. 21, in multiple winding portions L2 located in a same metal conductive layer 21, a winding portion L2 farthest from the hole-opening region W2 is an edge winding portion L2C. Dummy winding portions 51 may be arranged in one-to-one correspondence with edge winding portions L2C. A dummy winding portion 51 is located between a corresponding edge winding portion L2C and the display region AA, and the dummy winding portion 51 is located in a same layer as the corresponding edge winding portion L2C.

The difference from the array substrate 100 shown in FIG. 18 and FIG. 19 is that not only the outer winding portion L2A closest to the display region AA in a direction from the display region AA to the hole-opening region W2 is processed, but also the edge winding portion L2C closest to the display region AA in each metal conductive layer 21 is processed accordingly.

As in the above structure, since the dummy winding portions 51 are in one-to-one correspondence with the edge winding portions L2C, the dummy winding portions 51 can be used to balance the difference in the pattern density at both sides of the edge winding portion L2C in each metal conductive layer 21 provided with the winding portions L2, so as to prevent the problem of different etching rates at both sides of each edge winding portion L2C, and prevent the problem of a smaller line-width or even broken line of any one edge winding portion L2C, improving the quality of the array substrate 100. Moreover, the dummy winding portions 51 can also be used to balance the difference between the load of each edge winding portion L2C and the load of the other winding portions L2, improving the display effect of the display panel.

In addition, the dummy winding portions 51 and the edge winding portions L2C are in the same layer, so that the dummy winding portions 51 and the edge winding portion L2C can be formed by one patterning process, which may simplify the process of the array substrate 100.

It will be noted that the “same layer” refers to a layer structure formed by forming a film layer for forming specific patterns through a same film forming process and then performing a single patterning process using a same mask. Depending on different specific patterns, the patterning process may include exposure processes, development processes or etching processes, the specific patterns in the formed layer structure may be continuous or discontinuous, and these specific patterns may also be at different heights or have different thicknesses.

In some embodiments, as shown in combination with FIG. 20 and FIG. 21, along the direction V from the hole-opening region W2 to the display region AA, a distance C1 between a dummy winding portion 51 and an edge winding portion L2C adjacent thereto is set to be substantially equal to a distance C2 between any two adjacent winding portions L2. It may be convenient to simultaneously form the dummy winding portion 51 and the plurality of winding portions L2, thereby reducing the manufacturing difficulty of the array substrate 100. Furthermore, it may also be convenient to reduce the layout difficulty of the array substrate 100 and improve the regularity of the array substrate 100.

In addition, along the direction V from the hole-opening region W2 to the display region AA, a distance between two adjacent dummy winding portions 51 is substantially equal to the distance C2 between any two adjacent winding portions L2.

The above may be further convenient to simultaneously form the dummy winding portion 51 and the plurality of winding portions L2, thereby reducing the manufacturing difficulty of the array substrate 100 and improving the regularity of the array substrate 100.

It will be noted that due to the existence of certain uncontrollable errors (such as manufacturing process errors, equipment accuracy, or measurement errors), if a difference between the distance C1 between the dummy winding portion 51 and the edge winding portion L2C and the distance C2 between any two adjacent winding portions L2 fluctuates within a range of 10% C1 or 10% C2, it is also possible to consider that the distance C1 between the dummy winding portion 51 and the edge winding portion L2C and the distance C2 between any two adjacent winding portions L2 meet the requirement of equivalence.

In some embodiments, as shown in combination with FIG. 20 and FIG. 21, in the direction V from the hole-opening region W2 to the display region AA, a width of the dummy winding portion 51 is equal to a width of the winding portion L2. It may be convenient to simultaneously form the dummy winding portion 51 and the plurality of winding portions L2, thereby reducing the manufacturing difficulty of the array substrate 100. Furthermore, it may also be convenient to reduce the layout difficulty of the array substrate 100 and improve the regularity of the array substrate 100.

In summary, the dummy winding portion 51 does not need to be electrically connected to the pixel driving circuit, and other specification parameters can be the same as those of the plurality of winding portions L2. It may be convenient to simultaneously form the dummy winding portion 51 and the plurality of winding portions L2, thereby reducing the manufacturing difficulty of the array substrate 100 and improving the regularity of the array substrate 100.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. An array substrate, having a hole-opening region, a display region surrounding the hole-opening region, and a hole-peripheral region located between the hole-opening region and the display region, and comprising:
a substrate and a driving circuit layer located on the substrate, wherein
the driving circuit layer includes: a constant-voltage conductive ring and a plurality of signal lines, wherein
the plurality of signal lines include a plurality of target signal lines, the target signal lines each include a lead portion and a winding portion connected thereto, the lead portion extends from the hole-peripheral region to the display region, and the winding portion is located in the hole-peripheral region and is disposed along an edge of the hole-opening region; and
the constant-voltage conductive ring is located in the hole-peripheral region and is disposed around the hole-opening region; and an orthographic projection of the winding portion on the substrate is located between an orthographic projection of the constant-voltage conductive ring on the substrate and the hole-opening region.

2. The array substrate according to claim 1, wherein
the lead portion includes a first overlapping portion, an orthographic projection of the first overlapping portion on the substrate overlaps the orthographic projection of the constant-voltage conductive ring on the substrate, and areas of first overlapping portions of lead portions of the plurality of target signal lines are equal.

3. The array substrate according to claim 1, wherein the plurality of target signal lines include a plurality of first signal lines, and lead portions of the plurality of first signal lines extend along a first direction and are arranged along a second direction, the first direction intersecting the second direction; and
the plurality of first signal lines are divided into signal lines of a first part and signal lines of a second part; and along the second direction, lead portions of the signal lines of the first part and lead portions of the signal lines of the second part are located at two sides of the hole-opening region, respectively.

4. The array substrate according to claim 3, wherein the plurality of target signal lines further include a plurality of second signal lines, and lead portions of the plurality of second signal lines extend along the second direction and are arranged in the first direction; and
the plurality of second signal lines are divided into signal lines of a third part and signal lines of a fourth part; and along the first direction, lead portions of the signal lines of the third part and lead portions of the signal lines of the fourth part are located at two sides of the hole-opening region, respectively.

5. The array substrate according to claim 4, wherein the first signal lines include gate control signal lines, and the second signal lines include data signal lines.

6. The array substrate according to claim 4, wherein the driving circuit layer includes multiple metal conductive layers stacked on the substrate, wherein
along a direction away from the substrate, the multiple metal conductive layers are a first gate metal layer, a second gate metal layer, a first wiring metal layer, and a second wiring metal layer;
in the plurality of first signal lines: winding portions of a part of the first signal lines are located in the first gate metal layer, and winding portions of another part of the first signal lines are located in the second gate metal layer; and
in the plurality of second signal lines: winding portions of a part of the second signal lines are located in the first wiring metal layer, and winding portions of another part of the second signal lines are located in the second wiring metal layer.

7. The array substrate according to claim 1, wherein in a plurality of winding portions of the plurality of signal lines, a winding portion whose orthographic projection on the substrate is furthest away from the hole-opening region is an outer winding portion; and
the driving circuit layer further includes:
a dummy winding portion, wherein the dummy winding portion is located between the outer winding portion and the display region, and the dummy winding portion is in a same layer as the outer winding portion.

8. The array substrate according to claim 6, wherein in multiple winding portions located in a same metal conductive layer, a winding portion farthest from the hole-opening region is an edge winding portion; and
the driving circuit layer further includes:
dummy winding portions, wherein the dummy winding portions are in one-to-one correspondence with edge winding portions, and the dummy winding portions are each located between a corresponding edge winding portion and the display region, and the dummy winding portions are each located in a same layer as the corresponding edge winding portion.

9. The array substrate according to claim 7, wherein in a direction from the hole-opening region to the display region, a width of the dummy winding portion is equal to a width of the winding portion.

10. The array substrate according to claim 7, wherein in a direction from the hole-opening region to the display region, a distance between the dummy winding portion and the outer winding portion adjacent thereto is equal to a distance between any two adjacent winding portions.

11. The array substrate according to claim 1, wherein in a plurality of winding portions of the plurality of signal lines, a winding portion whose orthographic projection on the substrate is furthest away from the hole-opening region is an outer winding portion; and other than the outer winding portion, winding portions in the plurality of winding portions are each a first inner winding portion; and
in a direction from the hole-opening region to the display region, a width of the outer winding portion is d1, and a width of the first inner winding portion is d2, d1 being greater than d2.

12. The array substrate according to claim 6, wherein in multiple winding portions located in a same metal conductive layer, a winding portion farthest from the hole-opening region is an edge winding portion; and other than the edge winding portion, winding portions in the multiple winding portions are each a second inner winding portion; and
in a direction from the hole-opening region to the display region, a width of the edge winding portion is d1, and a width of the second inner winding portion is d2, d1 being greater than d2.

13. The array substrate according to claim 11, wherein 1.1 times d2 is less than or equal to d1, and d1 is less than or equal to 1.15 times d2 (1.1d2≤d1≤1.15d2).

14. The array substrate according to claim 11, wherein d1 is equal to 1.3 times d2 (d1=1.3d2).

15. The array substrate according to claim 1, wherein the driving circuit layer further includes a plurality of pixel driving circuits, a pixel driving circuit of the plurality of pixel driving circuits includes a driving transistor, and the plurality of pixel driving circuits are located in the display region; and
the driving circuit layer further includes:
a bottom shielding layer, located between the pixel driving circuits and the substrate, wherein the constant-voltage conductive ring is electrically connected to the bottom shielding layer; and the bottom shielding layer includes a plurality of shielding patterns, and an orthographic projection of a shielding pattern of the plurality of shielding patterns on the substrate covers an orthographic projection of the driving transistor on the substrate, and two adjacent shielding patterns are connected to each other.

16. The array substrate according to claim 15, wherein the constant-voltage conductive ring is in a same layer as the bottom shielding layer.

17. The array substrate according to claim 16, wherein the bottom shielding layer further includes a conductive connection portion, and the conductive connection portion is connected between the constant-voltage conductive ring and the shielding pattern; and
the driving circuit layer further includes a plurality of connection through-holes, and an orthographic projection of the conductive connection portion on the substrate is non-overlapping with orthographic projections of the connection through-holes on the substrate.

18. The array substrate according to claim 17, wherein a minimum distance between an orthographic projection of the conductive connection portion on the substrate and an orthographic projection of a connection through-hole of the plurality of connection through-holes on the substrate is greater than or equal to 3 μm.

19. The array substrate according to claim 17, wherein the conductive connection portion is in a same layer as the constant-voltage conductive ring;
the conductive connection portion includes a first conductive connection portion, and the first conductive connection portion intersects the constant-voltage conductive ring to form a first acute angle and a first space; and
the driving circuit layer further includes a first compensation portion, and the first compensation portion is in the same layer as the constant-voltage conductive ring; and the first compensation portion is located in the first space, the first compensation portion intersects the first conductive connection portion to form a first included angle, and the first compensation portion intersects the constant-voltage conductive ring to form a second included angle, wherein the first included angle and the second included angle are both greater than or equal to 90°.

20. A display panel, comprising:
the array substrate according to claim 1; and
a light-emitting device layer, located on a side of the array substrate away from the substrate.
